(19) United States
(12) Patent Application Publication
(10) Pub. No.: US 2026/0136935 A1
(43) Pub. Date: May 14, 2026

(54) PACKAGE STRUCTURE INCLUDING A HYBRID TIM STRUCTURE AND METHODS FOR FORMING THE SAME

(71) Applicant: Taiwan Semiconductor Manufacturing Company Limited, Hsinchu (TW)

(72) Inventors: Yi-Huan Liao, Hsinchu (TW); Chih-Hao Chen, Taipei City (TW); Po-Yuan Cheng, New Taipei City (TW); Pu Wang, Hsinchu City (TW); Li-Hui Cheng, New Taipei City (TW)

(21) Appl. No.: 18/942,977

(22) Filed: Nov. 11, 2024

(51) Int. Cl. H01L 23/427; H01L 21/48; H01L 21/60; H01L 23/00; H01L 23/04; H01L 23/373; H01L 25/16; H01L 25/18

(52) U.S. Cl. CPC H10W 40/73; H10W 40/037; H10W 40/258; H10W 72/071; H10W 76/12; H10W 74/15; H10W 90/00; H10W 90/724; H10W 90/734

(57) ABSTRACT

A package structure includes a package substrate, a semiconductor module on the package substrate, a package lid on the semiconductor module and attached to the package substrate, and a hybrid thermal interface material (TIM) structure between the semiconductor module and the package lid, including a TIM layer and a vapor core heat spreader in the TIM layer.

### BACKGROUND

A package structure may include one or more semiconductor dies on a package substrate, and a package lid attached to the package substrate over the semiconductor dies. A thermal interface material (TIM) layer may be located between the semiconductor dies and the package lid to help dissipate heat.

The TIM layer may enhance heat transfer from the semiconductor dies to the package lid. The TIM layer may achieve this by filling in microscopic air gaps and irregularities on the surfaces of both the semiconductor dies and the package lid. The air gaps might otherwise trap air which is a poor conductor of heat.

In some instances, a hot spot may be formed in the TIM layer (e.g., a metal TIM layer) of the package structure (e.g., chip-on-wafer-on-substrate) due to a non-uniform thermal energy generation of the semiconductor dies. In particular, a hot spot may be formed in a region of the TIM layer over a semiconductor die that is a high heat source (e.g., produces a relatively large amount of heat). In other instances, a region of the TIM layer over a semiconductor die that is a low heat source (e.g., produces a relatively small amount of heat) may dissipate little heat.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a vertical cross-sectional view of a package structure according to one or more embodiments.

FIG. 1B is a plan view (e.g., top-down view) of the package structure according to one or more embodiments.

FIG. 1C is a detailed vertical cross-sectional view of a portion of the package structure according to one or more embodiments.

FIG. 2A is a perspective view of the hybrid TIM structure according to one or more embodiments.

FIG. 2B is a vertical cross-sectional view of the hybrid TIM structure according to one or more embodiments.

FIG. 2C is a vertical cross-sectional view of the hybrid TIM structure according to one or more embodiments.

FIG. 3A is a vertical cross-sectional view of an intermediate structure including the package substrate having package substrate upper bonding pads and package substrate lower bonding pads, according to one or more embodiments.

FIG. 3B illustrates a vertical cross-sectional view of an intermediate structure in which the semiconductor module may be mounted on the package substrate, according to one or more embodiments.

FIG. 3C illustrates a vertical cross-sectional view of an intermediate structure including the semiconductor module in a first flux jetting process according to one or more embodiments.

FIG. 3D illustrates a vertical cross-sectional view of an intermediate structure in which the package underfill layer may be formed on the package substrate according to one or more embodiments.

FIG. 3E illustrates a vertical cross-sectional view of an intermediate structure in which the SMDs may be attached to the package substrate according to one or more embodiments.

FIG. 3F illustrates a vertical cross-sectional view of an intermediate structure including the semiconductor module and SMDs in a second flux jetting process according to one or more embodiments.

FIG. 3G illustrates a vertical cross-sectional view of an intermediate structure in which the lower TIM portion may be placed on the BSM layer according to one or more embodiments.

FIG. 3H illustrates a vertical cross-sectional view of an intermediate structure including the lower TIM portion in a third flux jetting process according to one or more embodiments.

FIG. 3I illustrates a vertical cross-sectional view of an intermediate structure in which the vapor core heat spreader may be placed on the lower TIM portion according to one or more embodiments.

FIG. 3J illustrates a vertical cross-sectional view of an intermediate structure including the vapor core heat spreader in a fourth flux jetting process according to one or more embodiments.

FIG. 3K illustrates a vertical cross-sectional view of an intermediate structure in which the upper TIM portion may be placed on the vapor core heat spreader according to one or more embodiments.

FIG. 3L illustrates a vertical cross-sectional view of an intermediate structure including the upper TIM portion in a fifth flux jetting process according to one or more embodiments.

FIG. 3M illustrates a vertical cross-sectional view of an intermediate structure in which the adhesive layer may be applied to the package substrate according to one or more embodiments.

FIG. 3N illustrates a vertical cross-sectional view of an intermediate structure in which the package lid may be placed on the package substrate according to one or more embodiments.

FIG. 3O illustrates a vertical cross-sectional view of an intermediate structure in which the package lid may be heat clamped onto the package substrate according to one or more embodiments.

FIG. 3P illustrates a vertical cross-sectional view of an intermediate structure in which the BGA including the plurality of solder balls may be formed on the package substrate according to one or more embodiments.

FIG. 4 is a flow chart illustrating a method of making the package structure according to one or more embodiments.

FIG. 5 is a vertical cross-sectional view of the package structure having a first alternative configuration, according to one or more embodiments.

FIG. 6A is a vertical cross-sectional view of the package structure having the second alternative configuration, according to one or more embodiments.

FIG. 6B is a vertical cross-sectional view of an intermediate structure in the making of the second alternative configuration of the package structure according to one or more embodiments.

FIG. 7 is a vertical cross-sectional view of a package structure having a third alternative configuration, according to one or more embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

The structure of a TIM layer may contribute to an uneven dissipation of heat in the package structure. In particular, a structure of TIM1 (e.g., a TIM layer between the semiconductor dies and the package lid) may have a width greater than thickness (e.g., less than 0.5 mm in the z direction but about 40 mm to 90 mm in the x and y directions). As a result, TIM1 may dissipate heat much faster in a vertical direction than in a horizontal direction, contributing to the formation of hot spots in a region of TIM1 over a high heat source semiconductor die.

A portion of a package lid over a hot spot in TIM1 (e.g., a portion of the package lid over a high heat source semiconductor die) may, therefore, also include a hot spot. A portion of the package lid outside the hot spot in TIM1 (e.g., a portion of the package lid over a low heat source semiconductor die) may include a wasted region. The wasted region may contribute little to heat dissipation in the package structure. The hot spot in the package lid may become a root cause limiting a performance of the package structure. That is, the overall heat dissipation performance may be limited by the high heat source regions in the package structure.

Several specific approaches may be used to manage the hot spots caused by uneven heat distribution by the semiconductor dies. In particular, a physical layout of the semiconductor dies may be optimized so that high heat source semiconductor dies may be positioned to maximize heat spread across the package lid, minimizing the risk of hot spots in any one area of the TIM layer. As another approach, a TIM layer with higher thermal conductivity may be used over the high heat source semiconductor dies to improve heat transfer specifically in those areas. In addition, the thickness of the TIM layer over the high heat source semiconductor dies may also be increased to optimize thermal transfer.

In some cases, high-thermal-conductivity pads or inserts (like graphite or phase-change materials) may be applied over the high heat source semiconductor dies to enhance heat conduction (i.e., heat dissipation). These materials may be engineered to perform better over concentrated heat sources. In some instances, using a combination of thermal grease or paste with thermal pads or inserts for hot zones may enhance heat dissipation while keeping low heat source semiconductor dies adequately cooled.

A thicker or layered heat spreader (e.g., copper, aluminum) may also be formed on the package lid to help distribute the heat more evenly across the package lid. By conducting heat away from the hot spots more efficiently, the thermal load on the TIM layer may be reduced. Heat pipes may also be integrated into the heat spreader to help transport heat away from high heat source semiconductor dies and distribute the heat evenly, eliminating the need for the TIM layer to handle an excessive local heat.

Further, localized active cooling methods such as microfluidic cooling channels, liquid cooling, or direct heat sinks may be located over the high heat source semiconductor dies to carry away heat directly from the hot spot region. A vapor chamber may also be integrated in the heat spreader to allow the heat spreader to distribute heat more uniformly across the package lid, ensuring that heat from the high heat source semiconductor dies is not concentrated in small areas.

At least one embodiment of the present disclosure may include a vapor core heat spreader formed within a TIM layer (e.g., TIM1 structure). In at least one embodiment, a package structure may include a hybrid TIM1 including an ultra-thin type vapor core heat spreader (VCHS) formed within a metal TIM. The hybrid TIM1 may have excellent heat dissipation ability especially in a horizontal direction.

The VCHS may be sandwiched between metal TIMs (e.g., a lower TIM (mTIMa) and an upper TIM (mTIMb)) and bonded to the metal TIMs by intermetallic compounds (IMCs) at the interfaces with the lower TIM and upper TIM. The hybrid TIM1 may, therefore, have the structure “mTIMa/VCHS/mTIMb”. The VCHS may effectively dissipate heat in a horizontal direction, so that an uneven heat due to a local heat source may become uniform after passing through the VCHS. Thus, an overall thermal performance of the package structure may be enhanced.

In the hybrid TIM1 (e.g., composed of an ultra-thin VCHS and metal TIMs), the lower TIM (mTIMa) and upper TIM (mTIMb) may be bonded to the semiconductor die and package lid, respectively. The lower TIM (mTIMa) and upper TIM (mTIMb) may be a different or the same material (e.g., indium, indium base alloy, solder, and solder base alloy, etc.). An interface between the semiconductor die and lower TIM (mTIMa), an interface between the lower TIM (mTIMa) and the VCHS, an interface between the upper TIM (mTIMb) and VCHS, and an interface between the upper TIM (mTIMb) and package lid may each be bonded with IMCs.

In at least one embodiment, the ultra-thin VCHS may be characterized by a width W_vc and a height D_vc less than the width W_vc. The lower TIM (mTIMa) may be characterized by a width W_MT1 and height D_MT1 and the upper TIM (mTIMb) may be characterized by a width W_MT2 (e.g., substantially similar to the width W_MT1 of the lower TIM) and height D_MT2 (e.g., substantially similar to the height D_MT1 of the lower TIM).

In at least one embodiment, the width of ultra-thin VCHS, W_vc may satisfy W_vc≤W_die ≤W_MT1 and W_MT2. Where the lower TIM and the upper TIM include different materials and W_vc<W_MT1 and W_MT2, there may be additional interfaces with IMCs between the lower TIM and the upper TIM.

In at least one embodiment, each of D_vc, D_MT1 and D_MT2 may be in a range from 0.05 mm to 0.5 mm (e.g., D_vc=0.3 mm and D_MT1=D_MT2=0.1 mm). In that case, a thickness D of the hybrid TIM1 may satisfy D=D_vc+D_MT1+D_MT2≤1 mm.

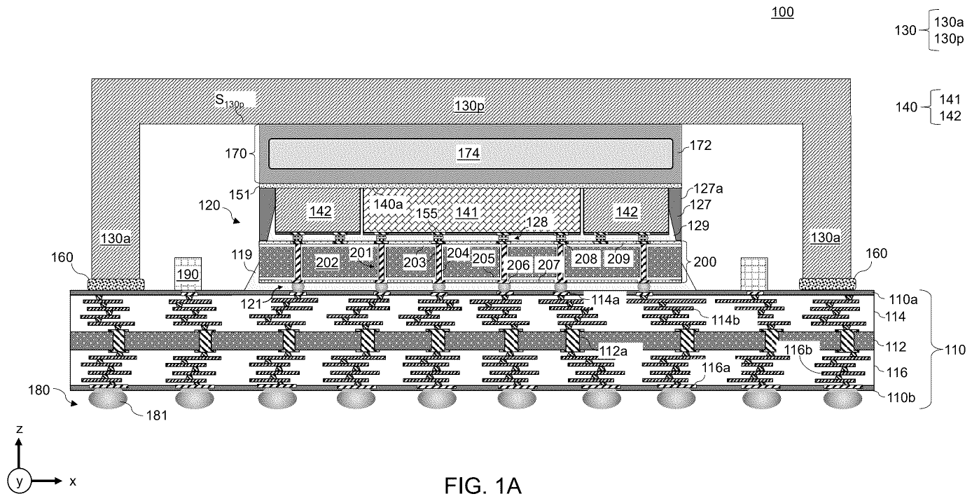

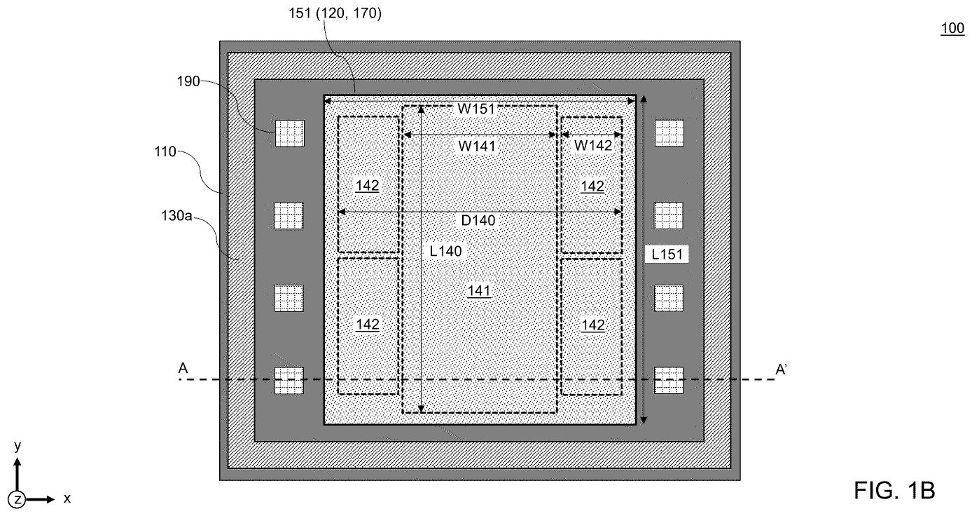

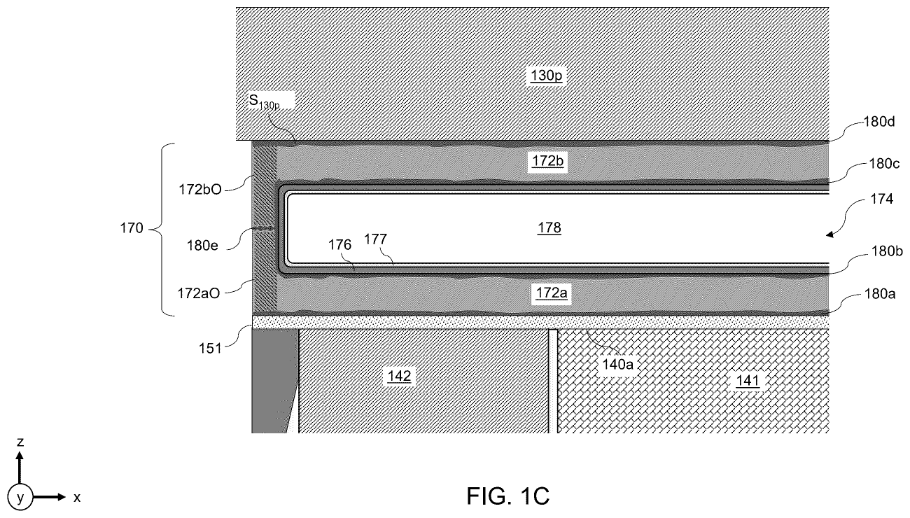

FIG. 1A is a vertical cross-sectional view of a package structure 100 according to one or more embodiments. FIG. 1B is a plan view (e.g., top-down view) of the package structure 100 according to one or more embodiments. The vertical cross-sectional view in FIG. 1A is along the line A-A′ in FIG. 1B. FIG. 1C is a detailed vertical cross-sectional view of a portion of the package structure 100 according to one or more embodiments.

As illustrated in FIG. 1A, the package structure 100 may include a package substrate 110 and a semiconductor module 120 on the package substrate 110. The package structure 100 may also include a package lid 130 on the semiconductor module 120. The package lid 130 may include a package lid foot portion 130a attached to the package substrate 110. The package lid 130 may also include a package lid plate portion 130p connected to the package lid foot portion 130a.

The package structure 100 may also include a hybrid thermal interface material (TIM) structure 170 between the semiconductor module 120 and the package lid 130. The hybrid TIM structure 170 may include a TIM layer 172 and a vapor core heat spreader 174 in the TIM layer 172. The vapor core heat spreader 174 may help to dissipate heat in the x-direction and y-direction and thereby inhibit hot spot formation in the TIM layer 172. As a result, the vapor core heat spreader 174 may help to provide a uniform lateral distribution of heat in the package lid plate portion 130p and avoid having a wasted region in the package lid plate portion 130p (e.g., a region of the package lid plate portion 130p that contributes very little to heat dissipation).

The package substrate 110 may include a cored or coreless substrate. In at least one embodiment, for example, the package substrate 110 may include a core 112, a package substrate upper dielectric layer 114 formed on the core 112 (e.g., a first side or chip-side of the package substrate 110), and a package substrate lower dielectric layer 116 formed on the core 112 (e.g., a second side or board-side of the package substrate 110). In particular, the package substrate 110 may include a build-up film substrate such as an Ajinomoto build-up film (ABF) substrate. That is, in at least one embodiment, each of the package substrate upper dielectric layer 114 and the package substrate lower dielectric layer 116 may be described as an ABF layer.

The core 112 may help to provide rigidity to the package substrate 110. The core 112 may include, for example, an epoxy resin such as a bismaleimide triazine epoxy (BT epoxy) and/or a woven glass laminate. The core 112 may alternatively or in addition include an organic material such as a polymer material. In particular, the core 112 may include a dielectric polymer material such as polyimide (PI), benzocyclobutene (BCB) polymer, or polybenzobisoxazole (PBO). Other suitable dielectric materials are within the contemplated scope of disclosure.

The core 112 may include one or more through vias 112a. The through vias 112a may extend from a lower surface of the core 112 to an upper surface of the core 112. The through vias 112a may allow an electrical connection between the package substrate upper dielectric layer 114 and the package substrate lower dielectric layer 116. The through vias 112a may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

The package substrate upper dielectric layer 114 may be formed on an upper surface of the core 112. The package substrate upper dielectric layer 114 may include a plurality of layers and, in particular, may include a build-up film (e.g., ABF). The package substrate upper dielectric layer 114 may also include an organic material such as a polymer material. In particular, the package substrate upper dielectric layer 114 may include a dielectric polymer material such as polyimide (PI), benzocyclobutene (BCB), or polybenzobisoxazole (PBO). Other suitable dielectric materials are within the contemplated scope of disclosure.

The package substrate upper dielectric layer 114 may also include one or more package substrate upper bonding pads 114a on a chip-side surface of the package substrate upper dielectric layer 114. The package substrate upper bonding pads 114a may be exposed on the chip-side surface of the package substrate upper dielectric layer 114. The package substrate upper dielectric layer 114 may also include one or more metal interconnect structures 114b. The metal interconnect structures 114b may electrically couple the package substrate upper bonding pads 114a to the through vias 112a in the core 112. The metal interconnect structures 114b may include metal layers (e.g., copper traces) and metal vias connecting the metal layers. The metal interconnect structures 114b may constitute a redistribution layer (RDL) structure in the package substrate 110. The package substrate upper bonding pads 114a and the metal interconnect structures 114b may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

A package substrate upper passivation layer 110a may be formed on the chip-side surface of the package substrate upper dielectric layer 114. The package substrate upper passivation layer 110a may at least partially cover the package substrate upper bonding pads 114a. The upper passivation layer 110a may include silicon oxide, silicon nitride, low-k dielectric materials such as carbon-doped oxides, extremely low-k dielectric materials such as porous carbon doped silicon dioxide, a combination thereof or other suitable material.

The package substrate lower dielectric layer 116 may be formed on a lower surface of the core 112. The package substrate lower dielectric layer 116 may also include a plurality of layers and, in particular, may include a build-up film (e.g., ABF). The package substrate lower dielectric layer 116 may also include an organic material such as a polymer material. In particular, the package substrate lower dielectric layer 116 may include a dielectric polymer material such as polyimide (PI), benzocyclobutene (BCB), or polybenzobisoxazole (PBO). Other suitable dielectric materials are within the contemplated scope of disclosure.

The package substrate lower dielectric layer 116 may include one or more package substrate lower bonding pads 116a on a board-side surface of the package substrate lower dielectric layer 116. The package substrate lower dielectric layer 116 may also include one or more metal interconnect structures 116b. The metal interconnect structures 116b may electrically couple the package substrate lower bonding pads 116a to the through vias 112a in the core 112. The metal interconnect structures 116b may include metal layers (e.g., copper traces) and metal vias connecting the metal layers. The metal interconnect structures 116b may constitute a redistribution layer (RDL) structure in the package substrate 110. The package substrate lower bonding pads 116a and the metal interconnect structures 116b may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

A package substrate lower passivation layer 110b may be formed on the board-side surface of the package substrate lower dielectric layer 116. The package substrate lower passivation layer 110b may at least partially cover the package substrate lower bonding pads 116a. The package substrate lower passivation layer 110b may include silicon oxide, silicon nitride, low-k dielectric materials such as carbon-doped oxides, extremely low-k dielectric materials such as porous carbon doped silicon dioxide, a combination thereof or other suitable material.

A ball-grid array (BGA) 180 including a plurality of solder balls 181 may be formed on the board-side surface of the package substrate 110. The solder balls 181 may allow the package structure 100 to be securely mounted on a substrate such as a printed circuit board (PCB) and electrically coupled to the PCB substrate. The solder balls 181 may contact the package substrate lower bonding pads 116a, respectively. The solder balls 181 may therefore be electrically connected to the package substrate upper bonding pads 114a by way of the package substrate lower bonding pads 116a, the metal interconnect structures 116b, the through vias 112a and the metal interconnect structures 114b. The solder balls 181 of the BGA 180 may be formed in a two-dimensional array on the board-side surface of the package substrate 110. The solder balls 181 may be located, for example, over at least a large portion of the package substrate 110, including under the package lid foot portion 130a and under the semiconductor module 120.

As illustrated in FIG. 1A, the semiconductor module 120 may be located in a central portion of the package substrate 110. The semiconductor module 120 may have a width in the x-direction that is less than a width of the package substrate 110 in the x-direction. The semiconductor module 120 may also have a length in the y-direction that is less than a length of the package substrate 110 in the y-direction.

The semiconductor module 120 may include an interposer 200 and one or more semiconductor dies 140 (e.g., electronic dies, photonic dies, etc.; see FIG. 1B) on the interposer 200. The semiconductor module 120 may be attached by C4 bumps 121 to the package substrate upper bonding pads 114a in the package substrate 110. The C4 bumps 121 may include a metal pillar (e.g., copper pillar; not shown) and a solder bump (e.g., SnAg solder bump) on the metal pillar. The solder bump may be collapsed to join the metal pillar of the C4 bump 121 to the package substrate upper bonding pads 114a.

A package underfill layer 119 may be formed on the package substrate 110 under and around the semiconductor module 120. The package underfill layer 119 may also be formed around the C4 bumps 121. The package underfill layer 119 may thereby securely fix the semiconductor module 120 to the package substrate 110. The package underfill layer 119 may be formed of an epoxy-based polymeric material. Other suitable materials may be used for the package underfill layer 119.

The semiconductor module 120 is not limited to any particular configuration. The semiconductor module 120 may include, for example, a flip chip-chip scale package design, a chip-on-wafer-on-substrate design, an integrated fan-out design, and so on. In at least one embodiment, the interposer 200 may be omitted from the semiconductor module 120. In such embodiments, the semiconductor dies 140 may be attached directly to the package substrate 110.

The interposer 200 of the semiconductor module 120 may include an inorganic interposer. The interposer 200 may alternatively or additionally include an organic interposer (not shown). The interposer 200 may include a semiconductor material layer 202. In at least one embodiment, the semiconductor material layer 202 may include a silicon-based semiconductor material. The semiconductor material layer 202 may include single crystalline silicon or polycrystalline silicon. The semiconductor material layer 202 may be undoped or doped with electrical dopants such as p-type dopants or n-type dopants.

The interposer 200 may include a plurality of via cavities 201 in the semiconductor material layer 202. The via cavities 201 may extend in the z-direction through an entire thickness of the semiconductor material layer 202. A lateral dimension (such as the diameter) of the via cavities 201 may be in a range from 0.5 micron to 10 microns, such as from 1 micron to 6 microns, although lesser and greater lateral dimensions may also be used. In at least one embodiment, the pattern of the array of via cavities 201 may have a two-dimensional periodicity over the interposer 200.

An insulating liner 203 may be formed in peripheral portions of the via cavities 201 and on an upper surface of the semiconductor material layer 202. The insulating liner 203 may include, for example, silicon oxide, silicon nitride, low-k dielectric materials such as carbon-doped oxides, extremely low-k dielectric materials such as porous carbon doped silicon dioxide, a combination thereof or other suitable material. The insulating liner 203 may have a thickness in a range from 1 % to 20 %, such as from 2 % to 5 % of the lateral dimension of the via cavities 201.

A plurality of through silicon vias (TSVs) 204 may be located in the plurality of via cavities 201, respectively. The TSVs 204 and the insulating liner 203 may substantially fill the via cavities 201. The TSVs 204 may include at least one conductive material, such as at least one metallic material, in a central portion of the via cavities 201. The TSVs 204 may include, for example, a combination of a metallic barrier material (such as TiN, TaN, WN, MoN, TiC, TaC, WC, etc.) and a metallic fill material (such as Cu, Co, Ru, Mo, W, etc.). Other suitable metallic barrier materials and metallic fill materials are within the contemplated scope of disclosure.

The interposer 200 may also include a lower insulating layer 205 on a bottom surface of the semiconductor material layer 202. The lower insulating layer 205 may join the insulating liner 203 in the via cavities 201. The lower insulating layer 205 may include a material that is the same or similar to the material of the insulating liner 203. The lower insulating layer 205 may include, for example, silicon oxide, silicon nitride, low-k dielectric materials such as carbon-doped oxides, extremely low-k dielectric materials such as porous carbon doped silicon dioxide, a combination thereof or other suitable material.

The interposer 200 may further include interposer lower bonding pads 206 on the TSVs 204 on a board-side surface of the interposer 200. The interposer 200 may further include a lower passivation layer 207 on the board-side surface of the interposer 200. The lower passivation layer 207 may at least partially cover the interposer lower bonding pads 206. The C4 bumps 121 may be connected to the interposer lower bonding pads 206 on the board-side surface of the interposer 200, respectively. In at least one embodiment, the C4 bumps 121 may include underbump metallurgy (UBM) layers on the interposer lower bonding pads 206. The C4 bumps 121 may be located at least partially on the lower insulating layer 205. The lower insulating layer 205 may serve to electrically insulate the C4 bumps 121 from the semiconductor material layer 202.

The interposer 200 may further include interposer upper bonding pads 208 on the TSVs 204 on a chip-side surface of the interposer 200. The interposer 200 may further include an upper passivation layer 209 on the board-side surface of the interposer 200. The upper passivation layer 209 may at least partially cover the upper interposer bonding pads 208. The interposer lower bonding pads 206 and interposer upper bonding pads 208 may be substantially similar to the package substrate lower bonding pads 116a and package substrate upper bonding pads 114a. The lower passivation layer 207 and upper passivation layer 209 may be substantially similar to the package substrate lower passivation layer 110b and package substrate upper passivation layer 110a.

In at least one embodiment, the semiconductor module 120 may include an RDL structure (not shown) located on the chip-side surface of the interposer 200. The RDL structure may include a plurality of polymer layers and a plurality of redistribution layers stacked alternately. The redistribution layers may include a metal such as copper, aluminum, nickel, titanium, a combination thereof or other suitable metals. The redistribution layers may include metallic connection structures, i.e., metallic structures that provide electrical connection between nodes in the structure. In at least one embodiment, the redistribution layers may include a plurality of traces (lines) and a plurality of vias connecting the plurality traces to each other. The traces may be respectively located on the polymer layers and may extend in the x-direction (first horizontal direction) and y-direction (second horizontal direction) on an upper surface of the polymer layers. The redistribution layers may interconnect the semiconductor dies 140 and/or connect the semiconductor dies 140 to the TSVs 204 in the interposer 200.

The semiconductor dies 140 may be attached to the chip-side surface of the interposer 200 (or alternatively, to the RDL structure in embodiments in which the RDL structure is present). In particular, the semiconductor dies 140 may be flip-chip mounted on the upper surface of the interposer 200. That is, an active region of the semiconductor dies 140 may face the interposer 200 and a bulk semiconductor region of the semiconductor dies 140 may be opposite the active region.

The semiconductor dies 140 may include a substantially coplanar upper surface 140a (e.g., upper surface of the bulk semiconductor region). In particular, the upper surface 140a of the semiconductor dies 140 may be located at the same height measured from an upper surface of the upper passivation layer 209.

In at least one embodiment, the semiconductor dies 140 may be bonded to the upper interposer bonding pads 208 on the chip-side surface of the interposer 200 by microbumps 128. The microbumps 128 may each include a copper post and a solder bump on the copper post. In at least one embodiment, the semiconductor dies 140 may include one or more die bonding pads 155 electrically coupled to an active region of the semiconductor dies 140. The microbumps 128 may contact the die bonding pads 155 of the semiconductor dies 140. The die bonding pads 155 may include, for example, one or more layers and may include metals, metal alloys, and/or other metal-containing compounds (e.g., Cu, Al, Mo, Co, Ru, W, TiN, TaN, WN, etc.). Other suitable metal materials are within the contemplated scope of disclosure.

A module underfill layer 129 may be formed (e.g., individually or collectively) under and around each of the semiconductor dies 140. The module underfill layer 129 may also be formed around the microbumps 128. The module underfill layer 129 may thereby fix each of the semiconductor dies 140 to the interposer 200. The module underfill layer 129 may be formed of an epoxy-based polymeric material. Other suitable metal materials are within the contemplated scope of disclosure.

Instead of utilizing the microbumps 128 and module underfill layer 129, the semiconductor dies 140 may alternatively be bonded to the interposer 200 by a hybrid bond which may also be known as direct bonding or wafer-to-wafer bonding. The hybrid bond may include a metallic portion and a dielectric portion. In at least one embodiment, the hybrid bond may include a metal-metal bond and a dielectric-dielectric bond (e.g., an oxide-oxide bond). In particular, the hybrid bond may include a bond between the die bonding pads 155 and the interposer upper bonding pads 209, and a bond between a dielectric layer (e.g., oxide layer) on the semiconductor dies 140 and a dielectric layer (e.g., oxide layer) on the interposer 200 such as the upper passivation layer 209.

The semiconductor dies 140 may include a first semiconductor die 141 and a second semiconductor die 142 adjacent the first semiconductor die 141. Each of the semiconductor dies 140 may include, for example, a singular semiconductor die structure, a system-on-chip die, or a system-on-integrated chips die, and may be implemented by chip-on-wafer-on-substrate technology or integrated fan-out on substrate technology. In particular, each of the semiconductor dies 140 may include, for example, a semiconductor chip or chiplet for a high performance computing (HPC) application, an artificial intelligence (AI) application, and a 5G cellular network application, a logic die (e.g., mobile application processor, microcontroller, etc.), or a memory die (e.g., high-bandwidth memory (HBM) die, hybrid memory cube (HMC), dynamic random access memory (DRAM) die, a Wide I/O die, a M-RAM die, a R-RAM die, a NAND die, static random access memory (SRAM), etc. ), a central processing unit (CPU) chip, graphics processing unit (GPU) chip, field-programmable gate array (FPGA) chip, networking chip, application-specific integrated circuit (ASIC) chip, artificial intelligence/deep neural network (AI/DNN) accelerator chip, etc., a co-processor, accelerator, an on-chip memory buffer, a high data rate transceiver die, a I/O interface die, an IPD die, a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) die), a monolithic 3D heterogeneous chiplet stacking die, etc. Other dies are within the contemplated scope of this disclosure. In at least one embodiment, the first semiconductor die 141 may include a primary die (e.g., system-on-chip die) and the second semiconductor die 142 may include an ancillary die (e. g, DRAM die, HBM die, etc.) that supports an operation of the primary die.

A sidewall of the semiconductor dies 140 (e.g., die sidewall) may include one or more metal layers (not shown). The metal layers may include, for example, an adhesion layer, a diffusion barrier layer, and an anti-oxidation layer (e.g., a layer including gold).

The semiconductor module 120 may also include a molding material layer 127 on the interposer 200, on and around the semiconductor dies 140 and between the semiconductor dies 140. The molding material layer 127 may be formed on (e.g., cover) and bonded to one or more of the die sidewalls (e.g., all of the die sidewalls) on the semiconductor dies 140. In at least one embodiment, the semiconductor dies 140 may be substantially “embedded” within the molding material layer 127. The molding material layer 127 may also be formed on and bonded to a surface of the upper passivation layer 209 of the interposer 200 (or the RDL structure, if present).

An upper surface of the molding material layer 127 may be substantially uniform (e.g., flat). The upper surface of the molding material layer 127 may also be substantially coplanar with the upper surface 140a of the semiconductor dies 140. An outer sidewall of the molding material layer 127a may be substantially aligned with an outer sidewall of the interposer 200. In at least one embodiment, an outer sidewall of the semiconductor module 120 may be constituted at least in part by the outer sidewall 127a of the molding material layer 127 and at least in part by the outer sidewall of the interposer 200.

In at least one embodiment, the molding material layer 127 may be formed of a curable material that may cure to form a hard, solid structure. The molding material layer 127 may include, for example, epoxy molding compound (EMC). In at least one embodiment, the molding material layer 127 may include a polymeric material and in particular, an epoxy-based polymeric material. Other suitable molding materials may be used.

In at least one embodiment, the molding material layer 127 may have a coefficient of thermal expansion (CTE) that is substantially similar to a CTE of the interposer 200 (e.g., a CTE of silicon). In at least one embodiment, the molding material layer 127 may include an added material (e.g., filler material) for improving a property of the molding material layer 127 (e.g., thermal conductivity, CTE, etc.). The added material may include, for example, metal powder, metal oxide powder, etc. Other materials in the molding material layer 127 are within the contemplated scope of the disclosure.

The semiconductor module 120 may also include a backside metal (BSM) layer 151 on the upper surface of the molding material layer 127 and/or on the upper surface 140a of the dies 140 and/or on an upper surface of the module underfill layer 129 (e.g., between the semiconductor dies 140). The BSM layer 151 may be thermally conductive and improve a thermal dissipation characteristic of the semiconductor module 120. An outer edge of the BSM layer 151 may be substantially aligned with the outer sidewall 127a of the molding material layer 127.

In at least one embodiment, the BSM layer 151 may cover an entire upper surface of the semiconductor module 120, including an entirety of the upper surface of the molding material layer 127 and/or an entirety of the upper surface 140a of the dies 140 and/or an entirety of the upper surface of the module underfill layer 129. In at least one embodiment, the BSM layer 151 may cover only a portion of the upper surface of the semiconductor module 120, including a portion of the upper surface of the molding material layer 127 and/or a portion of the upper surface 140a of the dies 140 and/or a portion of the upper surface of the module underfill layer 129.

The BSM layer 151 may have a thickness in a range from 1 μm to 10 μm. Other suitable thicknesses may be used for the BSM layer 151. The BSM layer 151 may have a substantially uniform thickness. The BSM layer 151 may include a thermally conductive metal such as copper or a copper alloy. Other conductive metals such as titanium, nickel, gold and silver may be included in the BSM layer 151. Other suitable materials may also be included in the BSM layer 151.

The hybrid TIM structure 170 may be located on the BSM layer 151. In particular, the TIM layer 172 of the hybrid TIM structure 170 may contact the BSM layer 151. The TIM layer 172 may include one or more layers. As illustrated in FIG. 1A, an outer sidewall of the TIM layer 172 may be substantially aligned with an outer sidewall of the BSM layer 151. Alternatively, at least a portion of the TIM layer 172 may extend laterally (e.g., in the x-y plane) beyond the outer sidewall of the BSM layer 151. In at least one embodiment, a center of the TIM layer 172 (e.g., in the x-direction and y-direction) may be substantially aligned with a center of the semiconductor module 120 including a center of the BSM layer 151.

The TIM layer 172 may have a low bulk thermal impedance and high thermal conductivity. The TIM layer 172 may cover an entire area of the upper surface of the BSM layer 151. In at least one embodiment, the TIM layer 172 may be attached to the upper surface of the BSM layer 151 by a thermally conductive adhesive (not shown).

In at least one embodiment, the TIM layer 172 may include one or more metals. The TIM layer 172 may include, for example, a low-melting-temperature (LMT) metal TIM or liquid metal TIM. The TIM layer 172 may include one or more metals such as indium, an indium-based alloy, tin, solder (e.g., a tin-containing alloy such as SnAg), a solder-based alloy, gallium, silver, etc. The TIM layer 172 may include, for example, an indium base, silver base, solder base, gallium base, etc. The solder base may include tin and one or more other elements such as copper, silver, bismuth, indium, zinc, antimony, etc. Other metals in the TIM layer 172 are within the contemplated scope of this disclosure.

The TIM layer 172 may alternatively or additionally include other materials such as a thermal grease, a thermal paste, a thermal film, a thermal adhesive, a thermal gap filler, a thermal pad (e.g., silicone), a thermal tape or a gel-type TIM (e.g., a cross-linked polymer film). In at least one embodiment, the TIM layer 172 may include graphite, carbon nanotubes (CNTs), phase-change material (PCM), etc. The PCM may include, for example, a polymer based PCM. In at least one embodiment, the PCM may change its phase from solid to high-viscosity semi liquid around 60° C. Other materials in the TIM layer 172 are within the contemplated scope of this disclosure.

The vapor core heat spreader 174 may be embedded in the TIM layer 172. In at least one embodiment, the vapor core heat spreader 174 may be surrounded on all sides by the TIM layer 172. In at least one embodiment, a center of the vapor core heat spreader 174 may be centrally located in the TIM layer 172 in the x-direction, y-direction and z-direction. In at least one embodiment, at least a portion of the vapor core heat spreader 174 is located over the second semiconductor dies 142. In at least one embodiment, an entirety of each of the second semiconductor dies 142 may be covered by the vapor core heat spreader 174. The vapor core heat spreader 174 may efficiently dissipate heat generated by the semiconductor dies 140 in the semiconductor module 120. The vapor core heat spreader 174 may utilize the principles of phase change cooling to distribute heat laterally in the x-direction and y-direction. The vapor core heat spreader 174 may thereby help to avoid hot spot regions and wasted regions in the package lid plate portion 130p.

In operation, the vapor core heat spreader 174 may include one or more fluids that may be evaporated in a high-temperature region of the vapor core heat spreader 174 (e.g., near a higher-temperature region of the TIM layer 172). The fluid vapor may then move to a cooler region of the vapor core heat spreader 174 (e.g., near a lower-temperature region of the TIM layer 172) where the fluid vapor is condensed. The condensed fluid may then the transported back to the high-temperature region by a capillary action. By this operation, the vapor core heat spreader 174 may spread heat laterally in the hybrid TIM structure 170.

As further illustrated in FIG. 1A, the package structure 100 may include one or more surface mounted devices (SMDs) 190 on the chip-side surface of the package substrate 110 adjacent the semiconductor module 120. The SMDs 190 may include, for example, a semiconductor die such as the semiconductor dies 140 described above. In at least one embodiment, the SMDs 190 may include a memory die such as a DRAM die, HBM die, etc. The SMDs 190 may be electrically coupled to the semiconductor module 120 (and the semiconductor dies 140 in the semiconductor module 120) through the package substrate 110. The SMDs 190 may also include non-functional dies (e.g., dummy dies) that may provide structural support to the package structure 100.

The SMDs 190 may also include, for example, an MLCC device, integrated circuits, passive components such as resistors, capacitors and inductors, active components such as two-terminal devices, diodes and three-terminal devices, and electromechanical devices such as switches/relays, connectors and micro-motors. In at least one embodiment the SMDs 190 may include transistors (e.g., metal oxide semiconductor field effect transistors (MOSFETs)), rectifiers and voltage regulators for power management applications.

The SMDs 190 may be attached to the package substrate 110 by surface mount technology (SMT). As with the semiconductor module 120, the SMDs 190 may be mounted on the package substrate upper bonding pads 114a. The SMDs 190 may therefore be electrically connected to the metal interconnect structures 114b in the package substrate upper dielectric layer 114. The SMDs 190 may, therefore, be electrically coupled to the semiconductor dies 140 through the package substrate 110 and the interposer 200.

As further illustrated in FIG. 1A, the package lid 130 may be located on the hybrid TIM structure 170 and may provide a cover for the semiconductor module 120. The package lid 130 may also provide cover for the SMDs 190 on the package substrate 110. A material of the package lid 130 may include, for example, a metal such as copper, nickel, aluminum, etc. The material of the package lid 130 may alternatively or additionally include a ceramic material or polymer material. Other suitable materials of the package lid 130 may be used.

The package lid foot portion 130a of the package lid 130 may be attached to the package substrate 110. The package lid foot portion 130p may extend in a substantially perpendicular direction from the package lid plate portion 130p. The package lid foot portion 130p may be connected to the package substrate 110 by an adhesive layer 160. The adhesive layer 160 may include, for example, epoxy adhesive or silicone adhesive. Other adhesives are within the contemplated scope of this disclosure.

The package lid plate portion 130p may be connected to the package lid foot portion 130a (e.g., an upper end of the package lid foot portion 130a). In at least one embodiment, the package lid plate portion 130p may be integrally formed as a unit with the package lid foot portion 130a. The package lid plate portion 130p may alternatively be formed separate from the package lid foot portion 130a and attached to the package lid foot portion 130a by an adhesive (not shown). The adhesive may be substantially similar to the adhesive layer 160 described above.

The package lid plate portion 130p may have a plate-shape extending, for example, in an x-y plane in FIG. 1A. An outer periphery of the package lid plate portion 130p may be substantially aligned with an outer periphery of the package lid foot portion 130a. The package lid plate portion 130p may be substantially parallel to an upper surface of the package substrate 110. The package lid plate portion 130p may include a central region that is formed over the semiconductor module 120. In at least one embodiment, a center point (in the x-y plane) of the central region may be substantially aligned with the center point of the semiconductor module 120 and/or with the center point of the hybrid TIM structure 170.

The package lid plate portion 130p may include a bottom surface S₁₃₀ₚ that contacts an upper surface of the TIM layer 172 of the hybrid TIM structure 170. The bottom surface S₁₃₀ₚ may extend across an underside of the package lid plate portion 130p. In at least one embodiment, the bottom surface S₁₃₀ₚ may extend between the package lid foot portion 130a on one side of package structure 100 to the package lid foot portion 130a on the opposite side of the package structure 100. In at least one embodiment, the bottom surface S₁₃₀ₚ may constitute substantially the entire underside of the package lid plate portion 130p.

Referring to FIG. 1B, the package lid plate portion 130p and hybrid TIM structure 170 are omitted in the top-down view of the package structure 100 in FIG. 1B for ease of understanding. As illustrated in FIG. 1B, an outer edge of the hybrid TIM structure 170 and the outer edge of the semiconductor module 120 may be substantially aligned with an outer edge of the BSM layer 151.

As illustrated in the plan view of FIG. 1B, the package lid 130 may have a width in the x-direction and length in the y-direction substantially similar (e.g., slightly less) that the width and length of the package substrate 110, respectively. The SMDs 190 may be formed in a columns extending in the y-direction on opposing sides of the semiconductor module 120. The package lid 130 (e.g., package lid foot portion 130a) may be formed around an entire periphery of the semiconductor module 120 and around all of the SMDs 190 on the package substrate 110. The package lid 130 may alternatively be formed around only a portion of the semiconductor module 120 and/or a portion of the SMDs 190.

As further illustrated in FIG. 1B, the package substrate 110 may have a substantially rectangular shape having a width in the x-direction greater than the length in y-direction. The package substrate 110 may alternatively have a substantially square shape. Each of the package lid foot portion 130a and semiconductor module 120 may have an outer shape that is substantially the same as an outer shape of the package substrate 110. Other shapes of the package substrate 110, package lid 130 and semiconductor module 120 are within the contemplated scope of disclosure.

The semiconductor module 120 may be arranged in a central portion of the package substrate 110 so that a space between the semiconductor module 120 and the package lid foot portion 130a is substantially uniform around the perimeter of the semiconductor module 120. The semiconductor dies 140 may have a substantially rectangular shape or alternatively a substantially square shape. Other shapes of the semiconductor dies 140 are within the contemplated scope disclosure. The semiconductor dies 140 may have a die width in the x-direction and a die length in the y-direction greater than the die width.

In at least one embodiment, the BSM layer 151 may have a width W151 and a length L151 that is greater than the width W151. A distance D140 between the outer sidewalls of the second semiconductor dies 142 on opposing sides of the first semiconductor die 141 may be less than the width W151 of the BSM layer 151. In at least one embodiment, the width W151 of the BSM layer 151 may be at least 5% greater than the distance D140. Further, the semiconductor dies 140 may have a longest length L140 (shown in FIG. 1B as a length of the first semiconductor die 141) less than the length L151 of the BSM layer 151. In at least one embodiment, the length L151 of the BSM layer 151 may be at least 5% greater than the longest length L140 of the semiconductor dies 140. In at least one embodiment, the first semiconductor die 141 may have a width W141 and the second semiconductor dies 142 may have a width W142 that is less than the width W141 of the first semiconductor die 141. In at least one embodiment, the width W142 of the second semiconductor dies 142 may be no greater than 50% of the width W141 of the first semiconductor die 141.

Although FIG. 1B illustrates the package structure 100 as including one (1) first semiconductor die 141 and four (4) second semiconductor dies 142 having a particular arrangement, the number and arrangement of the first semiconductor dies 141 and second semiconductor dies 142 are not limited to the number and arrangement in FIG. 1B.

Referring again to FIG. 1C, the hybrid TIM structure 170 may be bounded on the bottom by the BSM layer 151 and on the top by the bottom surface S₁₃₀ₚ of the package lid plate portion 130p. The TIM layer 172 of the hybrid TIM structure 170 may include a lower TIM portion 172a on a lower surface of the vapor core heat spreader 174 and an upper TIM portion 172b an upper surface of the vapor core heat spreader 174. The lower TIM portion 172a may contact an upper surface of the BSM layer 151. The lower TIM portion 172a and upper TIM portion 172b may include the same or different materials. For example, the lower TIM portion 172a may be composed of indium and the upper TIM portion 172b may be composed of solder.

The vapor core heat spreader 174 may be located between the lower TIM portion 172a and upper TIM portion 172b. The lower TIM portion 172a may include a lower TIM portion outer wall 172aO formed on a side of the vapor core heat spreader 174. The upper TIM portion 172b may include an upper TIM portion outer wall 172bO formed on the side of the vapor core heat spreader 174 above the lower TIM portion outer wall 172aO. The lower TIM portion outer wall 172aO may contact the upper TIM portion outer wall 172bO near a center (in the z-direction) of the vapor core heat spreader 174.

The vapor core heat spreader 174 may include an outer case 176. The outer case 176 may be made of a metal such as copper, copper alloy, aluminum or aluminum alloy. Other suitable materials may be used in the outer case 176. The vapor core heat spreader 174 may also include a wick 177 on an inner wall of the outer case 176. The wick 177 may be formed, for example, of a screen structure, a sintered structure (e.g., sintered powder, sintered copper) and/or a grooved structure. Other suitable structures may be used for the wick 177. The vapor core heat spreader 174 may also include an inner chamber 178 that may be surrounded by the outer case 176 and the wick 177. In at least one embodiment, the inner chamber 178 may constitute a vacuum chamber.

In at least one embodiment, a material of the lower TIM portion 172a (e.g., indium) may be different than a material of the BSM layer 151 (e.g., copper). In that case, a first IMC layer 180a may be formed between the lower TIM portion 172a and the BSM layer 151. The first IMC layer 180a may bond the lower TIM portion 172a to the BSM layer 151.

In at least one embodiment, a material of the lower TIM portion 172a (e.g., indium) may be different than a material of the outer case 176 of the vapor core heat spreader 174 (e.g., copper). In that case, a second IMC layer 180b may be formed between the lower TIM portion 172a and the vapor core heat spreader 174. The second IMC layer 180b may bond the lower TIM portion 172a to the outer case 176 of the vapor core heat spreader 174.

In at least one embodiment, a material of the upper TIM portion 172b (e.g., indium) may be different than a material of the outer case 176 of the vapor core heat spreader 174 (e.g., copper). In such an embodiment, a third IMC layer 180c may be formed between the upper TIM portion 172b and the vapor core heat spreader 174. The third IMC layer 180c may bond the upper TIM portion 172b to the outer case 176 of the vapor core heat spreader 174.

In at least one embodiment, a material of the upper TIM portion 172b (e.g., indium) may be different than a material of the package lid plate portion 130p (e.g., copper). In such an embodiment, a fourth IMC layer 180c may be formed between the upper TIM portion 172b and the package lid plate portion 130p. The fourth IMC layer 180d may bond the upper TIM portion 172b to the package lid plate portion 130p.

In at least one embodiment, a material of the upper TIM portion 172b (e.g., indium) may be different than a material of the lower TIM portion 172a (e.g., solder). In such an embodiment, an outer wall IMC layer 180e may be formed between the lower TIM portion outer wall 172aO and the upper TIM portion outer wall 172bO. The outer wall IMC layer 180e may bond the lower TIM portion outer wall 172aO to the upper TIM portion outer wall 172bO (e.g., bond the lower TIM portion 172a to the upper TIM portion 172b.

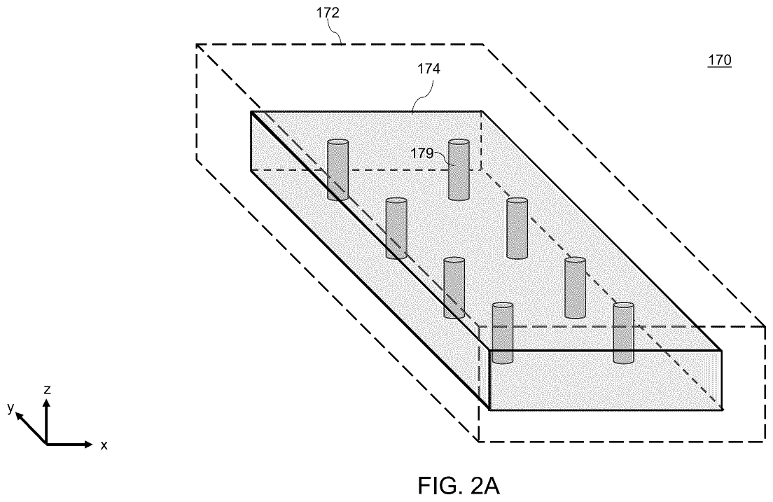

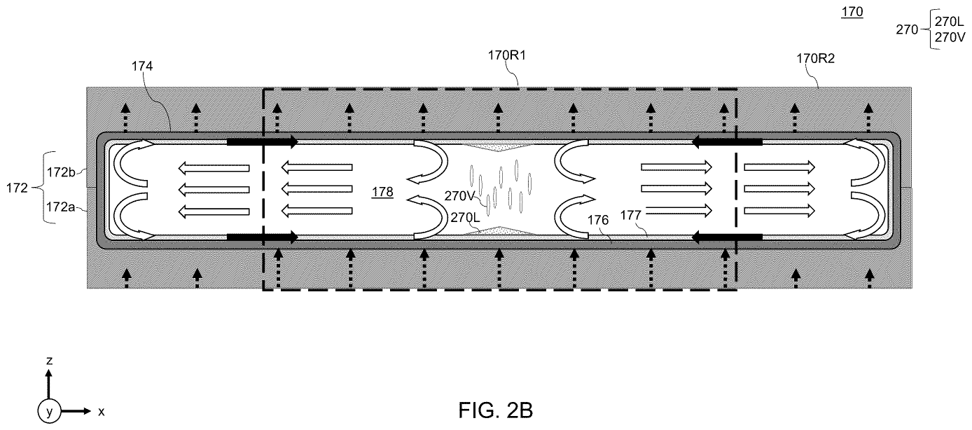

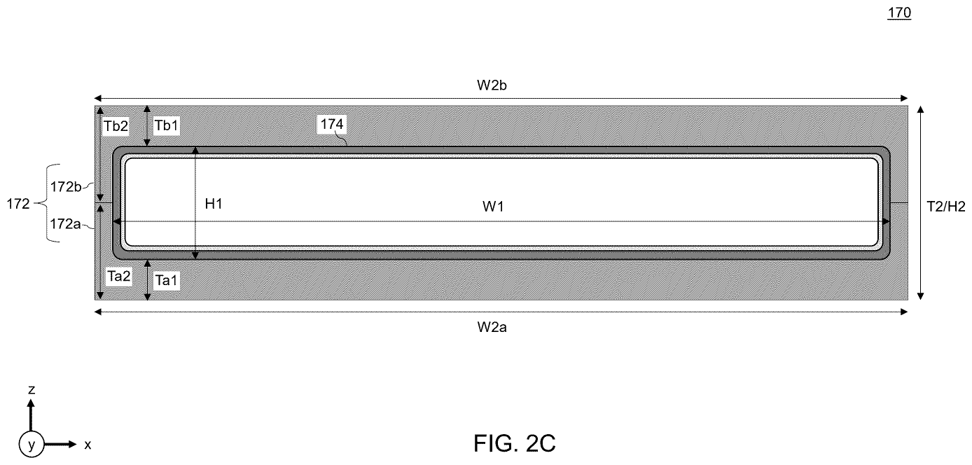

FIGS. 2A-2C illustrate the hybrid TIM structure 170 according to one or more embodiments. FIG. 2A is a perspective view of the hybrid TIM structure 170 according to one or more embodiments. As illustrated in FIG. 2A, the hybrid TIM structure 170 may have a substantially cuboid shape. In particular, the TIM layer 172 may have a substantially cuboid shape. The vapor core heat spreader 174 may be embedded in the TIM layer 172 and have a substantially cuboid shape. The shape of the vapor core heat spreader 174 may be substantially the same as the shape of the TIM layer 172, but with a smaller size (e.g., width in the x-direction, length in the y-direction and height in the z-direction).

As further illustrated in FIG. 2A, the vapor core heat spreader 174 may also include one or more support structures 179 in the inner chamber 178. The support structures 179 may extend in the z-direction from a bottom of the inner chamber 178 to a top of the inner chamber 178. The support structures 179 may be connected to a bottom of the outer case 176 and a top of the outer case 176. The support structures 179 may provide rigidity to outer case 176 and the vapor core heat spreader 174.

The support structures 179 may be formed, for example, in rows and columns in the inner chamber 178. The support structures 179 may alternatively be distributed randomly throughout the inner chamber 178. The support structures 179 may have a substantially cylindrical shape. In particular, the support structures 179 may have the shape of a circular cylinder, square cylinder, etc. Other shapes for the support structures 179 may be used.

In at least one embodiment, a material of the support structures 179 may be substantially the same as a material of the outer case 176. The material of the support structures 179 may include, for example, one or more metals or metal materials such as copper, a copper alloy, aluminum or an aluminum alloy. Other materials may be used in the support structures 179.

FIG. 2B is a vertical cross-sectional view of the hybrid TIM structure 170 according to one or more embodiments. The support structures 179 have been omitted from FIG. 2B for ease of understanding. The dashed arrows in FIG. 2B represent the direction and magnitude of heat transfer in the TIM layer 172. The shorter dashed arrows represent a lower amount of heat transfer than the longer dashed arrows.

As illustrated in FIG. 2B, the hybrid TIM structure 170 may have a first region 170R1 located over a high heat source such as the first semiconductor die 141. The hybrid TIM structure 170 may also have a second region 170R2 located over a low heat source such as the second semiconductor die 142. The second region 170R2 may be understood to mean any region of the hybrid TIM structure 170 outside the first region 170R1 (e.g., any region of the hybrid TIM structure 170 that is not located over a high heat source).

The vapor core heat spreader 170 may include a working fluid 270 in the inner chamber 178. The working fluid 270 may be present in the inner chamber 178 in the form of a working fluid liquid 270L and a working fluid vapor 270V. Heat generated in the first region 170R1 by operation of the first semiconductor dies 141 may cause the working fluid liquid 270L to be evaporated into the working fluid vapor 270V. The working fluid vapor 270V may expand laterally (shown by the white directional arrows in FIG. 2B) and carrying heat with it as it expands into the second region 170R2. In the second region 170R2, the working fluid vapor 270V is condensed into working fluid liquid 270L. The working fluid liquid 270L may then the transported (shown by the black directional arrows in FIG. 2B) in the wick 177 back to the first region 170R1 by a capillary action.

As illustrated in FIG. 2B, the magnitude of heat transfer in the lower TIM portion 172a of the second region 170R2 is low (e.g., shown by shorter dashed arrows). However, the magnitude of heat transfer in the upper TIM portion 172b of the second region 170R2 is high (e.g., shown by longer dashed arrows). In addition, the magnitude of heat transfer in the upper TIM portion 172b of the first region 170R1 is less than the magnitude of heat transfer in the lower TIM portion 172a of the first region 170R1. This illustrates the lateral heat-spreading action of the vapor core heat spreader 174 in the hybrid TIM structure 170.

FIG. 2C is a vertical cross-sectional view of the hybrid TIM structure 170 according to one or more embodiments. As illustrated in FIG. 2C, in at least one embodiment, the vapor core heat spreader 174 may have a width W1 and a height H1 that is less than the width W1. In at least one embodiment, the height H1 of the vapor core heat spreader 174 may be in a range from 0.05 mm to 0.5 mm. The TIM layer 172 may have a thickness T2 greater than the height H1 of the vapor core heat spreader 174. The hybrid TIM structure 170 may have a height H2 substantially equal to the thickness of the TIM layer 172. In at least one embodiment, the thickness of the TIM layer 172 (i.e., the height H2 of the hybrid TIM structure 170) may be less than or equal to 1 mm.

The lower TIM portion 172a may have a width W2a and the upper TIM portion 172b may have width W2b substantially the same as the width W2a. Thus, the TIM layer 172 may be considered to have a width W2a or W2b. The lower TIM portion 172a may have a first thickness Ta1 under the vapor core heat spreader 174 and a second thickness Ta2 on a side of the vapor core heat spreader 174 (e.g., a thickness of the lower TIM portion outer wall 172aO). The upper TIM portion 172b may have a first thickness Tb1 over the vapor core heat spreader 174 and a second thickness Tb2 on a side of the vapor core heat spreader 174 (e.g., a thickness of the upper TIM portion outer wall 172bO). A sum of the height H1 of the vapor core heat spreader 174, the first thickness Ta1 of the lower TIM portion 172a and the first thickness Tb1 of the upper TIM portion 172b may be equal to the height H2 of the hybrid TIM structure 170.

In at least one embodiment, the first thickness Ta1 of the lower TIM portion 172a may be substantially the same as the first thickness Tb1 of the upper TIM portion 172b. In at least one embodiment, each of the first thickness Ta1 of the lower TIM portion 172a and the first thickness Tb1 of the upper TIM portion 172b may be in a range from 0.05 mm to 0.5 mm. In at least one embodiment, the first thickness Tb1 of the upper TIM portion 172b may differ from the first thickness Ta1 of the lower TIM portion 172 a by less than 5%. In at least one embodiment, at least one of the first thickness Ta1 of the lower TIM portion 172a and the first thickness Tb1 of the upper TIM portion 172b may be less than the height H1 of the vapor core heat spreader 174. In at least one embodiment, a combined thickness of the lower TIM portion 172a and the upper TIM portion 172b (i.e., Ta1 +Tb1) may be less than the height H1 of the vapor core heat spreader 174. In one particular example, the height H1 of the vapor core heat spreader 174 may be about 0.3 mm and each of the first thickness Ta1 of the lower TIM portion 172a and the first thickness Tb1 of the upper TIM portion 172b may be about 0.1 mm.

In at least one embodiment, the second thickness Ta2 of the lower TIM portion 172a may be substantially the same as the second thickness Tb2 of the upper TIM portion 172b. In at least one embodiment, the second thickness Tb2 of the upper TIM portion 172b may differ from the second thickness Ta2 of the lower TIM portion 172a by less than 5%.

In at least one embodiment, the width W1 of the vapor core heat spreader 174 may be less than or equal to the distance D140 between the outer sidewalls of the second semiconductor dies 142 (see FIG. 1B). In at least one embodiment, the distance D140 between the outer sidewalls of the second semiconductor dies 142 (see FIG. 1B) may be less than or equal to each of the width W2a of the lower TIM portion 172a and the width W2b of the upper TIM portion 172b.

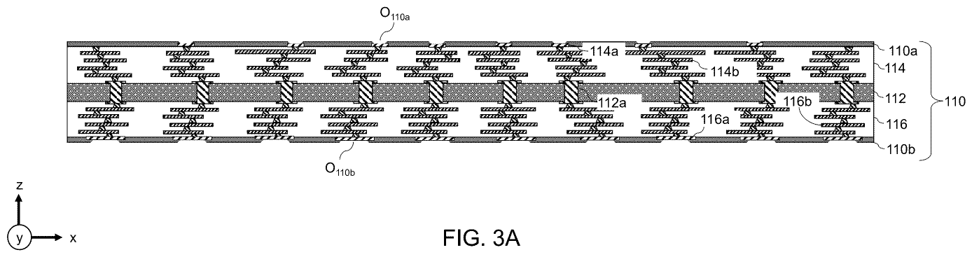

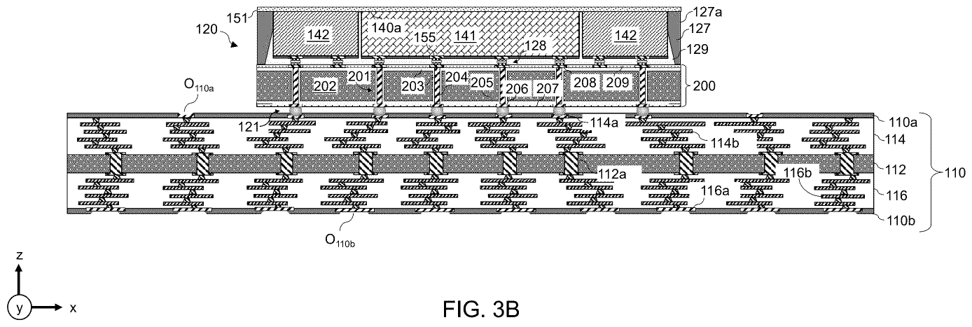

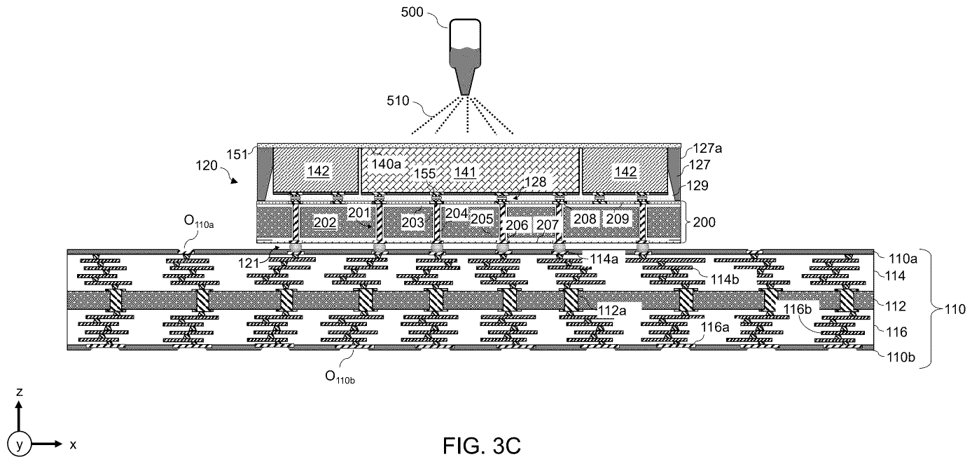

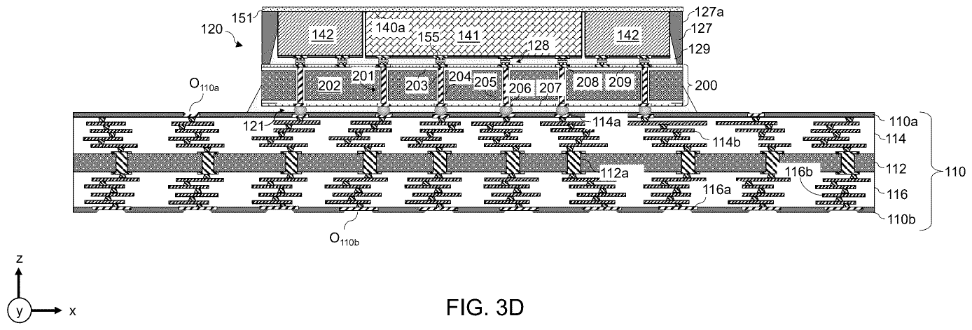

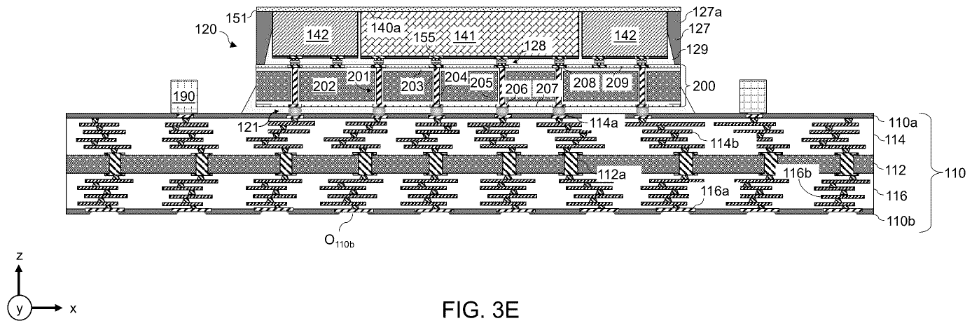

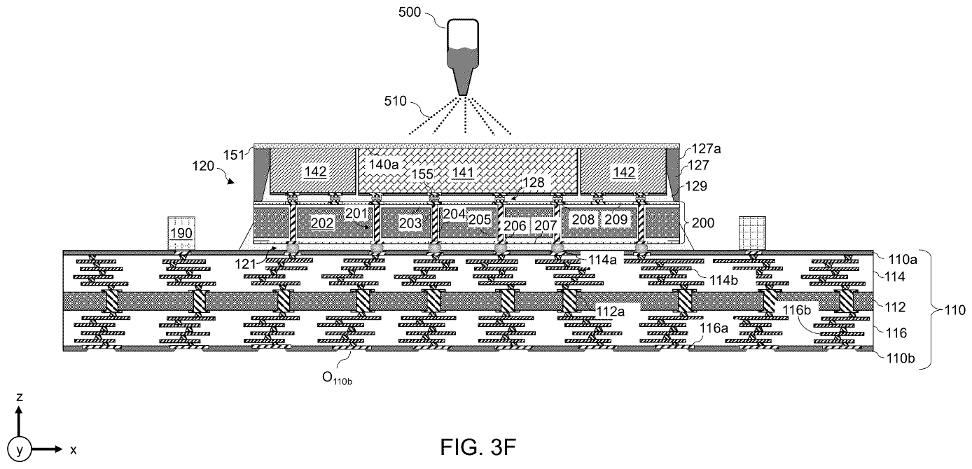

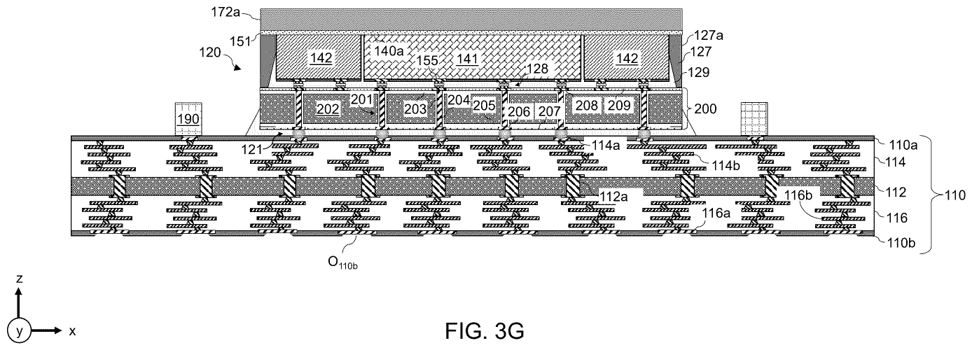

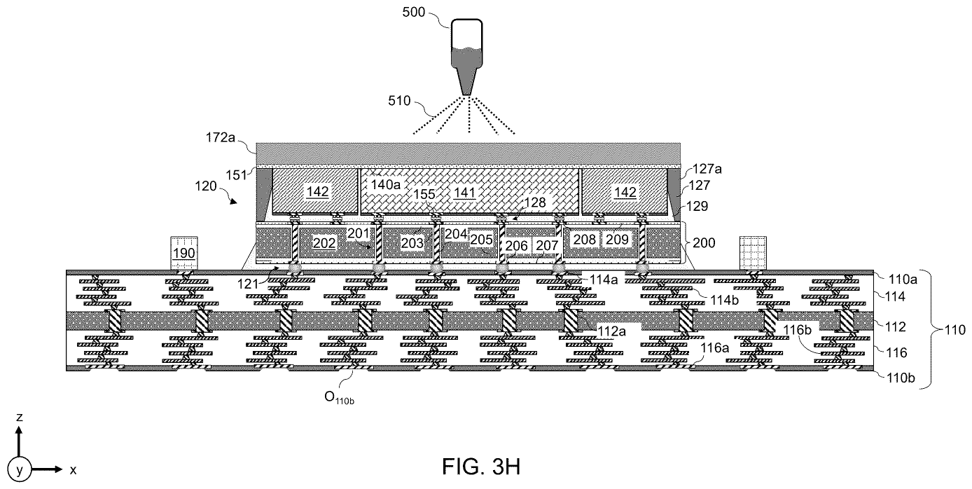

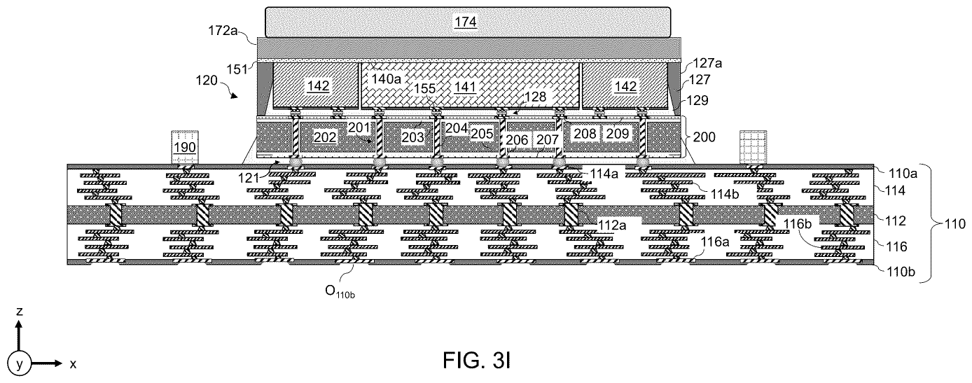

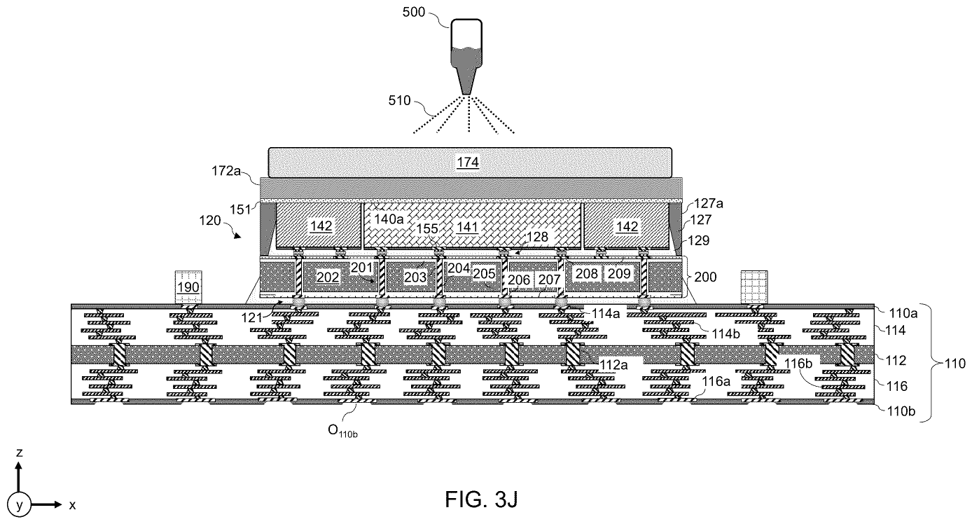

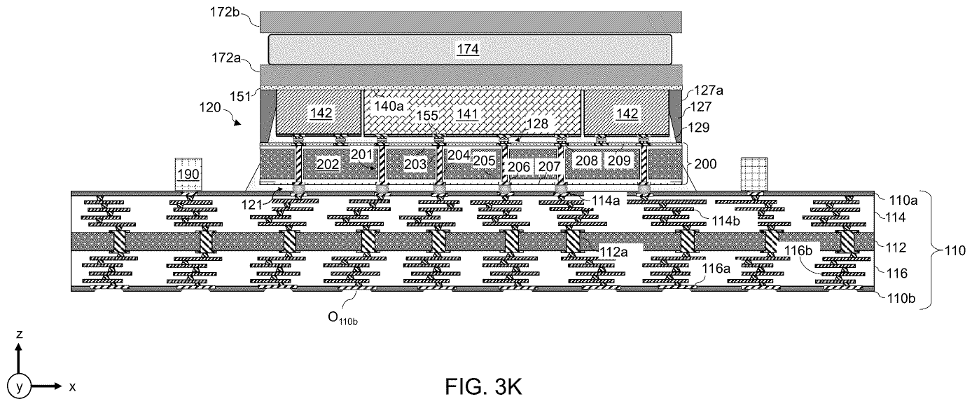

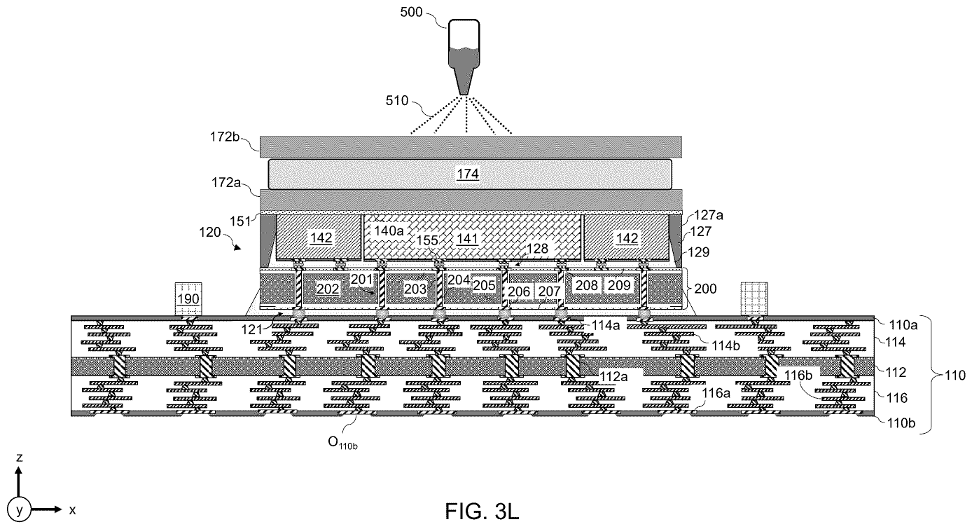

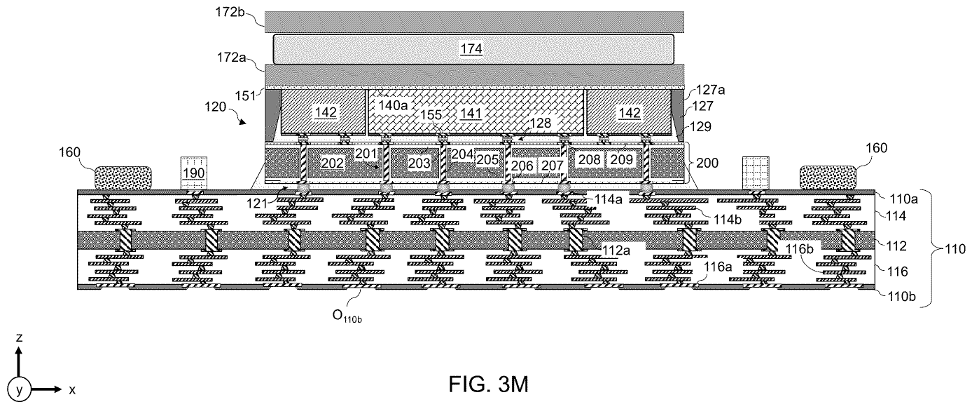

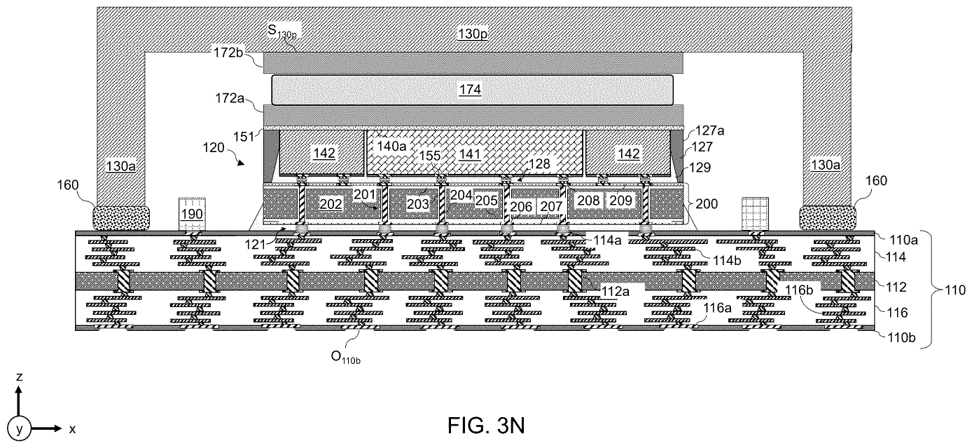

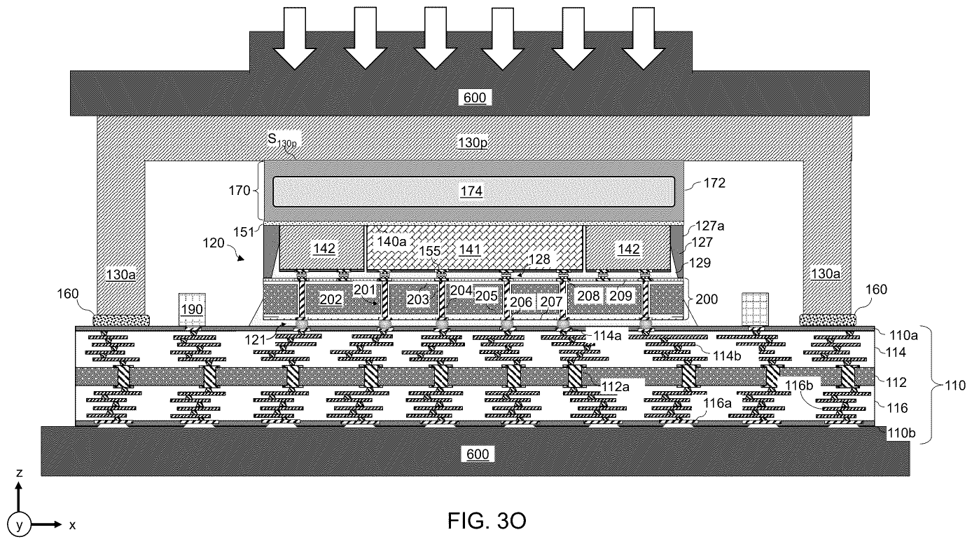

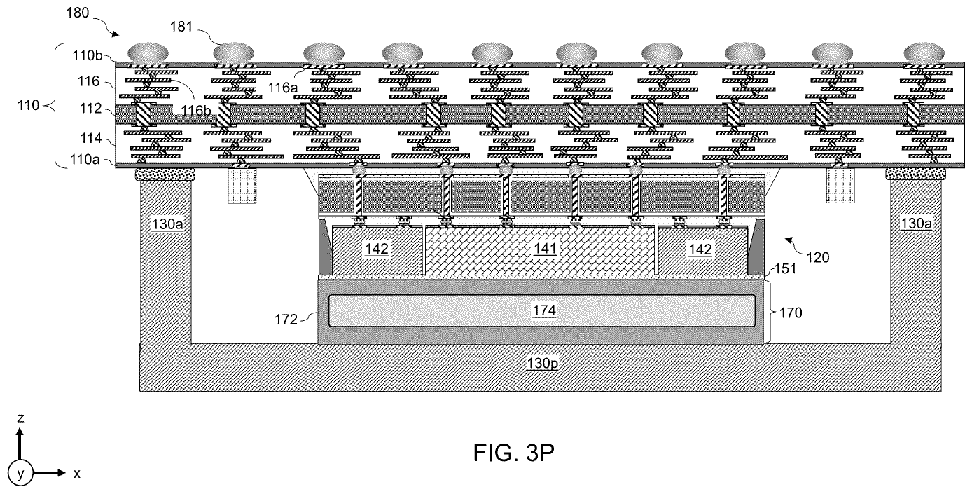

FIGS. 3A-3P illustrate various intermediate structures in a method of forming the package structure 100 according to one or more embodiments. FIG. 3A is a vertical cross-sectional view of an intermediate structure including the package substrate 110 having package substrate upper bonding pads 114a and package substrate lower bonding pads 116a, according to one or more embodiments. The package substrate 110 including the core 112, the package substrate upper dielectric layer 114, and the package substrate lower dielectric layer 116 may be provided.

The package substrate upper bonding pads 114a may be formed, for example, on an uppermost dielectric layer of the package substrate upper dielectric layer 114. The package substrate upper bonding pads 114a may be formed to contact the metal interconnect structures 114b. The package substrate upper bonding pads 114a may be formed by depositing a metal layer (e.g., copper, aluminum, or other suitable conductive materials) on the upper surface of the package substrate upper dielectric layer 114. The metal layer may then be patterned by etching (e.g., by wet etching, dry etching, etc.) to form the package substrate upper bonding pads 114a. Other suitable metal layer materials and etching processes may be within the contemplated scope of disclosure.

The package substrate lower bonding pads 116a may be formed, for example, on a lowest dielectric layer of the package substrate lower dielectric layer 116. The package substrate lower bonding pads 116a may be formed to contact the metal interconnect structures 116b. The package substrate lower bonding pads 116a may be formed in a manner similar to the manner of forming the package substrate upper bonding pads 114a (e.g., depositing a metal layer, patterning the metal layer by etching, etc.).

After formation, the package substrate upper bonding pads 114a and package substrate lower bonding pads 116a may optionally undergo a surface roughening treatment (e.g., copper zarazara (CZ) treatment). In the surface roughening treatment, a surface of the package substrate upper bonding pads 114a (e.g., a copper surface) and surface of the package substrate lower bonding pads 116a (e.g., a copper surface) may be etched by an organic acid-type microetching solution, to create a super-roughened surface (e.g., copper surface). The uniquely-roughened copper surface topography of the package substrate upper bonding pads 114a and package substrate lower bonding pads 116a may help to achieve a high copper-to-resin adhesion.

The package substrate upper passivation layer 110a and package substrate lower passivation layer 110b may then be formed on the package substrate upper bonding pads 114a and package substrate lower bonding pads 116a, respectively. In at least one embodiment, the package substrate upper passivation layer 110a and package substrate lower passivation layer 110b may each include a solder resist layer (e.g., polymer material), also referred to as a solder mask. The package substrate upper passivation layer 110a may also be referred to as the upper solder resist layer 110a, and the package substrate lower passivation layer 110b may also be referred to as the lower solder resist layer 110b.

The package substrate upper passivation layer 110a and package substrate lower passivation layer 110b may be applied concurrently. The package substrate upper passivation layer 110a and package substrate lower passivation layer 110b may be applied, for example, as a liquid photo-imageable film. The liquid photo-imageable film can be applied, for example, by silk-screening or spraying the liquid photo-imageable film onto the surface of the package substrate 110. The liquid photo-imageable film may be applied over the package substrate upper bonding pads 114a and the package substrate lower bonding pads 116a. The package substrate upper passivation layer 110a and package substrate lower passivation layer 110b may alternatively be applied as a dry-film photo-imageable film that may be vacuum-laminated onto the surface of the package substrate 110 and over the package substrate upper bonding pads 114a and package substrate lower bonding pads 116a, respectively. The package substrate upper passivation layer 110a and package substrate lower passivation layer 110b may alternatively or additionally be formed, for example, by chemical vapor deposition (CVD), physical vapor deposition (PVD), spin coating, lamination, or other suitable deposition technique.

The package substrate upper passivation layer 110a and package substrate lower passivation layer 110b may be applied to have a thickness that is slightly greater than a thickness of the package substrate upper bonding pads 114a and package substrate lower bonding pads 116a, respectively. Alternatively, the package substrate upper passivation layer 110a and package substrate lower passivation layer 110b may be applied so as to have an upper surface that is substantially coplanar with an upper surface of the package substrate upper bonding pads 114a and package substrate lower bonding pads 116a, respectively.

Openings O₁₁₀ₐ may then be formed in the package substrate upper passivation layer 110a so as to expose the upper surface of the package substrate upper bonding pads 114a. Openings O_{110b} may be formed in the package substrate lower passivation layer 110b to expose an upper surface of the package substrate lower bonding pads 116a. The openings O₁₁₀ₐ and the openings O_{110b} may be formed, for example, by using a photolithogra O_{110b} phic process. In at least one embodiment, the openings O₁₁₀ₐ and the openings O110b may be formed in separate photolithographic processes.

The photolithographic process (e.g., processes) used to form the openings O₁₁₀ₐ may include forming a patterned photoresist mask (not shown) on the package substrate upper passivation layer 110a, and etching (e.g., wet etching, dry etching, etc.) the exposed upper surface of the package substrate upper passivation layer 110a through openings in the photoresist mask. The photoresist mask may be subsequently removed by ashing, dissolving the photoresist mask or by consuming the photoresist mask during the etch process.

The photolithographic process (e.g., processes) used to form the openings O_{110b} may include forming a patterned photoresist mask (not shown) on the package substrate lower passivation layer 110b, and etching (e.g., wet etching, dry etching, etc.) the exposed upper surface of the package substrate lower passivation layer 110b through openings in the photoresist mask. The photoresist mask may be subsequently removed by ashing, dissolving the photoresist mask or by consuming the photoresist mask during the etch process.

After the openings O₁₁₀ₐ are formed in the package substrate upper passivation layer 110a and the openings O_{110b} are formed in the package substrate lower passivation layer 110b, the package substrate upper passivation layer 110a (upper solder resist layer) and the package substrate lower passivation layer 110b (lower solder resist layer) may be cured such as by a thermal cure or ultraviolet (UV) cure.

FIG. 3B illustrates a vertical cross-sectional view of an intermediate structure in which the semiconductor module 120 may be mounted on the package substrate 110, according to one or more embodiments. The semiconductor module 120 may be formed, for example, in a wafer level process in which a plurality of the semiconductor modules 120 are formed at the same time and in the same series of steps on one wafer (e.g., silicon wafer). As part of that wafer level process, after the molding material layer 127 is formed around the semiconductor dies 140 and cured, a wafer grinding step may be performed on the backside of the wafer including the molding material layer 127. The wafer grinding step may expose the upper surface 140a of the semiconductor dies 140.

After the wafer grinding step, the wafer may be cleaned and polished. The BSM layer 151 may then be formed on the backside of the wafer. The BSM layer 151 may be formed, for example, by an electrochemical plating process (also known as ECP or an electroplating process). Other methods of forming the BSM layer 151 (e.g., deposition, lamination, etc.) on the semiconductor module 120 are within the contemplated scope of disclosure.

In the electrochemical plating process, the silicon wafer may be cleaned thoroughly to remove any contaminants or particles that could interfere with the plating process. A plating solution (e.g., electrochemical plating solution, ECP solution or electrolyte solution) containing metal ions (e.g., copper ions) is then prepared. The plating solution may allow for the transport of copper ions from the anode to the cathode (the silicon wafer) during the plating process. The plating solution may contain a metal salt (e.g., copper salt) dissolved in a suitable solvent. The silicon wafer (the cathode) may be connected to the negative terminal of a direct current (DC) power supply. A piece of metal such as copper (e.g., the anode) may be connected to the positive terminal of the power supply. Both the cathode and anode may be submerged in the plating solution. In instances in which the power supply is turned on, metal ions (e.g., copper ions) from the plating solution may be attracted to the silicon wafer (cathode) due to the electrical potential difference. The metal ions may gain electrons at the cathode and deposit onto the silicon wafer, forming the BSM layer 151. After the desired thickness of the BSM layer 151 is achieved, the wafer may be removed from the plating solution, rinsed thoroughly to remove any residual electrolyte, and dried.

Generally, an electrochemical plating process may be used to form different types of copper including randomly arranged crystal copper, copper (111) and amorphous copper by varying the process parameters. In particular, a textured structure (e.g., the BSM layer 151) or a non-textured structure may be formed by varying process parameters such as additives, pH values of the plating solution and electrochemical plating mode (e.g., DC mode or pulse mode). For example, to form a textured structure (e.g., Cu (111)), the electrochemical plating process may utilize both DC mode and pulse mode, a small amount of additive and a plating solution with an acidic pH. Alternatively, to form a non-textured structure (e.g., Cu(100) or amorphous copper), the electrochemical plating process may utilize DC mode, a large amount of additive and a plating solution with an acidic pH.

After the BSM layer 151 is formed, a singulation process may be performed to separate the semiconductor module 120 from the wafer. First, a laser grooving step may be performed on the wafer (e.g., on the BSM layer 151). Then, a dicing saw may be used to singulate each of the individual semiconductor modules 120 included in the wafer.

The semiconductor module 120 may then be mounted on the package substrate 110, for example, by a flip chip bonding (FCB) process. The semiconductor module 120 may be positioned over the package substrate 110, for example, by an electromechanical pick-and-place (PNP) machine. The C4 bumps 121 (e.g., solder bumps) on the semiconductor module 120 may then be lowered onto the package substrate upper bonding pads 114a through the openings O₁₁₀ₐ (see FIG. 3A) in the package substrate upper passivation layer 110a. The intermediate structure including the semiconductor module 120 and package substrate 110 may then be heated in order to collapse the C4 bumps 121 and bond the C4 bumps 121 to the package substrate upper bonding pads 114a. In at least one embodiment, laser assisted bonding (LAB) may be used to reflow the C4 bumps 121 so that the semiconductor module 120 may be attached to the package substrate upper bonding pads 114a.

FIG. 3C illustrates a vertical cross-sectional view of an intermediate structure including the semiconductor module 120 in a first flux jetting process according to one or more embodiments. After attaching the semiconductor module 120 to the package substrate 110, one or more processes may be used to clean the BSM layer 151 and the package substrate 110 and maintain the surface of the BSM layer 151 and the surface of the package substrate 110. Such processes may include, for example, flux cleaning, pre-bake and plasma processes.

As illustrated in FIG. 3C, in a first flux jetting process, a flux 510 may be applied to the intermediate structure including the semiconductor module 120. The flux 510 may be used to clean the upper surface of the semiconductor module 120 (e.g., BSM layer 151) and the upper surface of the package substrate 110. The flux 510 may help facilitate formation of a joint between the BSM layer 151 and the hybrid TIM structure 170 (e.g., a TIM layer including a metal such as indium or gallium). The flux 510 may remove impurities (e.g., oxides) from the surface of the BSM layer 151 and the upper surface of the package substrate 110. The flux 510 may also inhibit reoxidation of the BSM layer 151 during the soldering process, and reduce the surface tension and the viscosity of a metal (e.g., indium in the hybrid TIM structure 170). The flux 510 may also improve the attachment of the package underfill layer 119 that is subsequently formed on the package substrate 110.

The flux 510 may include, for example, a rosin flux, organic acid flux or inorganic acid flux. Other suitable flux materials are within the contemplated scope of this disclosure. The flux may be applied, for example, as a liquid. As illustrated in FIG. 3C, a pressurized sprayer 500 may spray the flux 510 in a liquid state onto the upper surface of the BSM layer 151 and the upper surface of the package substrate 110.

FIG. 3D illustrates a vertical cross-sectional view of an intermediate structure in which the package underfill layer 119 may be formed on the package substrate 110 according to one or more embodiments. After the cleaning process is performed, the package underfill layer 119 may be formed on the package substrate 110. The package underfill layer 119 be formed by applying a liquid material such as an epoxy-based polymeric material to the surface of the package substrate 110. As illustrated in FIG. 3C, the package underfill layer 119 may be formed (e.g., injected) under and around the semiconductor module 120 and the C4 bumps 121 and onto the package substrate 110. The package underfill layer 119 may then be cured, for example, in a box oven for duration in a range from 60 minutes to 120 minutes at a temperature in a range from 120° C. to 190° C. to provide the package underfill layer 119 with a sufficient stiffness and mechanical strength. After the package underfill layer 119 is cured, a testing process (FT1) may be performed to test the intermediate structure (e.g., semiconductor module 120 and package substrate 110).

FIG. 3E illustrates a vertical cross-sectional view of an intermediate structure in which the SMDs 190 may be attached to the package substrate 110 according to one or more embodiments. After the testing process is completed, the SMDs 190 (e.g., DRAM devices, multi-layer ceramic capacitor (MLCC) devices, etc.) may be attached to the package substrate 110. The process for attaching the SMDs 190 may be substantially similar as the process described above for attaching the semiconductor module 120 to the package substrate 110.

The SMDs 190 may be attached to the package substrate 110 using an electromechanical pick and place (PNP) machine (not shown). The SMDs 190 may be mounted on the surface of the package substrate 110 adjacent the semiconductor module 120. In at least one embodiment, a solder paste (not shown) may be applied to a region of the package substrate 110 defined by a 3D stencil. The SMDs 190 may then be positioned over the openings O₁₁₀ₐ and lowered onto the openings O₁₁₀ₐ. The SMDs 190 may then be attached to the package substrate 110 by solder bumps by using a reflow process.

In at least one embodiment, an SMD underfill layer (not shown) may then be applied to the package substrate 110 and under and around the SMDs 190. The SMD underfill layer may include a material substantially the same as the material of the package underfill layer 119. The SMD underfill layer may also be applied and cured in a manner substantially similar to the manner of applying and curing the package underfill layer 119 described above.

FIG. 3F illustrates a vertical cross-sectional view of an intermediate structure including the semiconductor module 120 and SMDs 190 in a second flux jetting process according to one or more embodiments. After attaching the semiconductor module 120 and SMDs 190 to the package substrate 110, one or more processes may be used to clean the BSM layer 151. Such processes may include, for example, a second flux jetting process, pre-bake and plasma processes. The second flux jetting process may be performed in a manner similar to the first flux jetting process (see FIG. 3C). In particular, a pressurized sprayer 500 may spray the flux 510 in a liquid state onto the upper surface of the BSM layer 151.

FIG. 3G illustrates a vertical cross-sectional view of an intermediate structure in which the lower TIM portion 172a may be placed on the BSM layer 151 according to one or more embodiments. In at least one embodiment, the lower TIM portion 172a may be placed on the BSM layer 151 by an electromechanical PNP machine. The lower TIM portion 172a may be positioned over the BSM layer 151 so that the outer edge of the lower TIM portion 172a is substantially aligned with the outer edge of the BSM layer 151 around an entire periphery of the BSM layer 151. The lower TIM portion 172a may then be lowered onto the BSM layer 151. In at least one embodiment, a thermally conductive adhesive (not shown) may be applied to the upper surface of the BSM layer 151. In that case, the lower TIM portion 172a may be placed on the adhesive and pressed onto the adhesive.

The lower TIM portion 172a when placed on the BSM layer 151 may have a thickness greater than the desired thickness Ta1 in the completed package structure 100 (see FIG. 2C). In at least one embodiment, the thickness of the lower TIM portion 172a placed on the BSM layer 151 may be in a range from 2% to 10% greater than the desired thickness Ta1 in the completed package structure 100. This may allow for the vapor core heat spreader 174 to be pressed into the lower TIM portion 172a in a subsequent heat clamping process when heating clamping the package lid 130 to the package substrate 110.

FIG. 3H illustrates a vertical cross-sectional view of an intermediate structure including the lower TIM portion 172a in a third flux jetting process according to one or more embodiments. After placing the lower TIM portion 172a on the BSM layer 151, one or more processes may be used to clean the lower TIM portion 172a. Such processes may include, for example, a third flux jetting process, pre-bake and plasma processes. The third flux jetting process may be performed in a manner similar to the first flux jetting process (see FIG. 3C). In particular, a pressurized sprayer 500 may spray the flux 510 in a liquid state onto the upper surface of the lower TIM portion 172a.

FIG. 3I illustrates a vertical cross-sectional view of an intermediate structure in which the vapor core heat spreader 174 may be placed on the lower TIM portion 172a according to one or more embodiments. In at least one embodiment, the vapor core heat spreader 174 may be placed on the lower TIM portion 172a by an electromechanical PNP machine. The vapor core heat spreader 174 may be positioned over the lower TIM portion 172a so that the vapor core heat spreader 174 is substantially centered on the lower TIM portion 172a in the x-direction and the y-direction. The vapor core heat spreader 174 may then be lowered onto the lower TIM portion 172a. In at least one embodiment, a thermally conductive adhesive (not shown) may be applied to the upper surface of the lower TIM portion 172a. In that case, the vapor core heat spreader 174 may be placed on the adhesive and pressed onto the adhesive.

FIG. 3J illustrates a vertical cross-sectional view of an intermediate structure including the vapor core heat spreader 174 in a fourth flux jetting process according to one or more embodiments. After placing the vapor core heat spreader 174 on the lower TIM portion 172a, one or more processes may be used to clean the vapor core heat spreader 174 and the exposed upper surface of the lower TIM portion 172a. Such processes may include, for example, a fourth flux jetting process, pre-bake and plasma processes. The fourth flux jetting process may be performed in a manner similar to the first flux jetting process (see FIG. 3C). In particular, a pressurized sprayer 500 may spray the flux 510 in a liquid state onto the upper surface of the vapor core heat spreader 174 and the exposed upper surface of the lower TIM portion 172a.

FIG. 3K illustrates a vertical cross-sectional view of an intermediate structure in which the upper TIM portion 172b may be placed on the vapor core heat spreader 174 according to one or more embodiments. In at least one embodiment, the upper TIM portion 172b may be placed on the vapor core heat spreader 174 by an electro-mechanical PNP machine. The upper TIM portion 172b may be positioned over the vapor core heat spreader 174 so that the upper TIM portion 172b is substantially centered on the vapor core head spreader 174. In particular, the upper TIM portion 172b may be positioned over the vapor core heat spreader 174 so that the outer edge of the upper TIM portion 172b is substantially aligned with the outer edge of the lower TIM portion 172a around an entire periphery of the lower TIM portion 172a. The upper TIM portion 172b may then be lowered onto the vapor core heat spreader 174. In at least one embodiment, a thermally conductive adhesive (not shown) may be applied to the upper surface of the vapor core heat spreader 174. In that case, the upper TIM portion 172b may be placed on the adhesive and pressed onto the adhesive.

The upper TIM portion 172b when placed on the vapor core heat spreader 174 may have a thickness greater than the desired thickness Tb1 in the completed package structure 100 (see FIG. 2C). In at least one embodiment, the thickness of the upper TIM portion 172b placed on the vapor core heat spreader 174 may be in a range from 2% to 10% greater than the desired thickness Tb1 in the completed package structure 100. This may allow for the vapor core heat spreader 174 to be pressed into the upper TIM portion 172b in a subsequent heat clamping process when heating clamping the package lid 130 to the package substrate 110.

FIG. 3L illustrates a vertical cross-sectional view of an intermediate structure including the upper TIM portion 172b in a fifth flux jetting process according to one or more embodiments. After placing the upper TIM portion 172b on the vapor core heat spreader 174, one or more processes may be used to clean the upper TIM portion 172b and an upper surface of the package substrate 110. Such processes may include, for example, a fifth flux jetting process, pre-bake and plasma processes. The fifth flux jetting process may be performed in a manner similar to the first flux jetting process (see FIG. 3C). In particular, a pressurized sprayer 500 may spray the flux 510 in a liquid state onto the upper surface of the upper TIM portion 172b and the upper surface of the package substrate 110.

FIG. 3M illustrates a vertical cross-sectional view of an intermediate structure in which the adhesive layer 160 may be applied to the package substrate 110 according to one or more embodiments. The adhesive layer 160 may be dispensed onto the package substrate 110 with a dispensing tool (e.g., automated dispensing tool). The dispensing tool may dispense the adhesive layer 160 in a frame shape around the semiconductor module 120. At the time of application, the adhesive layer 160 may be sufficiently rigid so as to form a semi-solid bead on the surface of the package substrate 110. In at least one embodiment, a viscosity of the adhesive layer 160 at the time of application may be 50,000 centipoise (cp) or greater. The shape of the semi-solid bead may remain substantially unchanged between the time of application by the dispensing tool and the later time of attaching the package lid 130. The location of the frame shape of the adhesive layer 160 may correspond to a location of the foot portion 130a of the package lid 130 (e.g., see FIG. 1B).

FIG. 3N illustrates a vertical cross-sectional view of an intermediate structure in which the package lid 130 may be placed on the package substrate 110 according to one or more embodiments. After the adhesive layer 160 is applied to the upper surface of the package substrate 110 the package lid 130 may be placed on the package substrate 110. In at least one embodiment, the package substrate 110 with the semiconductor module 120 may be placed on a surface. The package lid 130 may then be positioned over the package substrate 110, for example, by an electromechanical PNP machine. The package lid 130 may then be lowered down over the semiconductor module 120 and onto the package substrate 110. The foot portion 130a of the package lid 130 may then be aligned with the adhesive layer 160 formed on the package substrate 110. The package lid 130 may then be lowered down onto the package substrate 110 so that the package lid foot portion 130a contacts the adhesive layer 160.

FIG. 3O illustrates a vertical cross-sectional view of an intermediate structure in which the package lid 130 may be heat clamped onto the package substrate 110 according to one or more embodiments. The package lid 130 may be pressed downward onto package substrate 110 by a pressing for applied to the package lid plate portion 130p. The pressing force may be applied to the package lid plate portion 130p so that the package lid foot portion 130a is pressed onto the adhesive layer 160. The pressing forced may also be applied to the package lid plate portion 130p so that the bottom surface S130p of the package lid plate portion 130p is pressed onto the TIM layer 172 of the hybrid TIM structure 170.

As illustrated in FIG. 3O, the package lid 130 may then be heat clamped to the package substrate 110 with a heat clamp module 600 for a period of sufficient duration to allow the adhesive layer 160 to cure and form a secure bond between the package substrate 110 and the package lid 130. In at least one embodiment, the adhesive layer 160 is a snap-cure adhesive that may be cured by exposure to ultraviolet (UV) light.

The heat clamp module 600 may apply a uniform force across the upper surface of the package lid plate portion 130p. In at least one embodiment, the heat clamp module 600 may apply a pressure in a range of 0 psi to 25 psi, and heat the intermediate structure to a temperature in a range of 150° C. to 200° C. for a time period in a range from 0.5 minutes to 15 minutes.

The heat clamping with the heat clamp module 600 may soften or melt the lower TIM portion 172a and the upper TIM portion 172b. This may allow the vapor core heat spreader 174 to be pressed into the lower TIM portion 172a and the upper TIM portion 172b so that a thickness of the lower TIM portion 172a may be reduced to the desired thickness Ta1 and a thickness of the upper TIM portion 172b may be reduced to the desired thickness Tb1. Further, the softened or melted lower TIM portion 172a and the softened or melted upper TIM portion 172b may be caused to flow along the side of the vapor core heat spreader 174 and form the lower TIM portion outer wall 172aO and the upper TIM portion outer wall 172bO, respectively (see FIG. 1C). In at least one embodiment, the lower TIM portion outer wall 172aO may contact the upper TIM portion outer wall 172bO. In at least one embodiment, the lower TIM portion outer wall 172aO may melt together and combine with the upper TIM portion outer wall 172bO.

The heat clamping with the heat clamp module 600 may also assist in forming the various IMC layers in and on the hybrid TIM structure 170 (see FIG. 1C). In particular, the clamping of the heat clamp module 600 may assist in the formation of the first IMC layer 180a between the lower TIM portion 172a and the BSM layer 151, the second IMC layer 180b between the lower TIM portion 172a and the vapor core heat spreader 174, the third IMC layer 180c between the upper TIM portion 172b and the vapor core heat spreader 174, the fourth IMC layer 180c may be formed between the upper TIM portion 172b and the package lid plate portion 130p and the outer wall IMC layer 180e between the lower TIM portion outer wall 172aO and the upper TIM portion outer wall 172bO. The intermediate structure may additionally or alternatively be placed in a box oven to cure the adhesive layer 160 and form the various IMC layers.

FIG. 3P illustrates a vertical cross-sectional view of an intermediate structure in which the BGA 180 including the plurality of solder balls 181 may be formed on the package substrate 110 according to one or more embodiments. The plurality of solder balls 181 may be formed on the package substrate lower bonding pads 116a through the openings O110b in the package substrate lower passivation layer 110b (see FIG. 3A). The solder balls 181 may be formed, for example, by an electroplating process. The solder balls 181 may be formed, for example, so as to be located under the foot portion 130a and under the semiconductor module 120 and therebetween. The plurality of solder balls 181 may constitute the BGA 180 which may allow the package structure 100 to be securely mounted on a substrate such as a printed circuit board (PCB) and electrically coupled to the substrate.

At this point, one or more optional integrated passive devices (IPDs) (not shown) may be mounted on the board-side surface of the package substrate 110. The optional IPDs may be mounted in a process similar to the mounting process for the SMD described above. In particular, the mounting process may include a solder reflow process for electrically coupling the IPDs to the board-side surface of the package substrate 110. After the optional IPDs are mounted on the package substrate 110, additional processes may be used to clean the package substrate 110 and maintain the surface of the package substrate 110. Such processes may include, for example, flux cleaning, pre-bake and plasma processes. In particular, the processes may include a flux jetting process similar to the first flux jetting described above with respect to FIG. 3C.

An IPD underfill layer (not shown) may then be applied to the package substrate 110 and under and around the IPDs. The IPD underfill layer may include a material substantially the same as the material of the package underfill layer 119. The IPD underfill layer may also be applied and cured in a manner substantially similar to the manner of applying and curing the package underfill layer 119 described above.

After the optional IPD underfill layer is cured, one or more processes may be performed prior to final testing (FT2). The processes may include, for example, one or more inspections such as an inspection by an optical inspection system (e.g., ICOS, HEXA, etc.) and a final visual inspection. These inspections may provide a sanity check (e.g., checking z-height, package appearance, etc.) of the completed package structure 100. A final testing process may then be performed on the package structure 100.

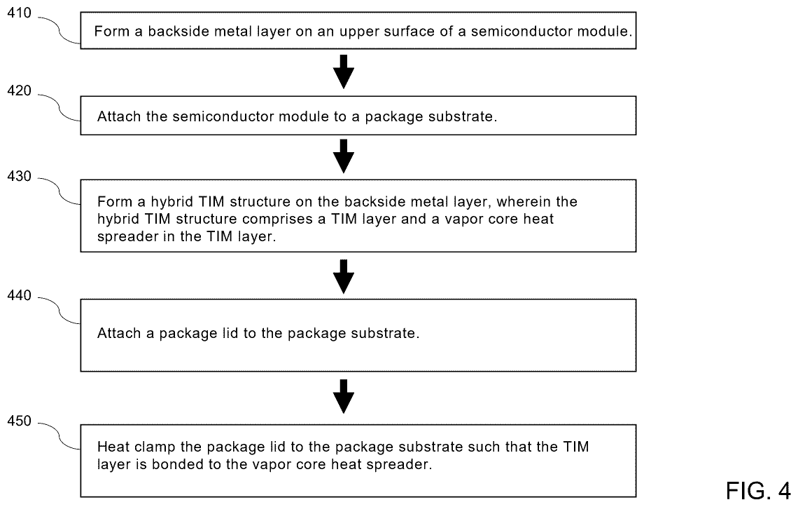

FIG. 4 is a flow chart illustrating a method of making the package structure 100 according to one or more embodiments. The method of making the package structure 100 is not limited to the steps listed in the flowchart of FIG. 4. Further, the method illustrated in FIG. 4 is not intended to limit the method to a specific sequence of steps.

Step 410 of the method includes forming a backside metal layer on an upper surface of a semiconductor module. Step 420 includes attaching the semiconductor module to a package substrate. Step 430 includes forming a hybrid TIM structure on the backside metal layer, wherein the hybrid TIM structure comprises a TIM layer and a vapor core heat spreader in the TIM layer. Step 440 includes attaching a package lid to the package substrate. Step 450 includes heat clamping the package lid to the package substrate such that the TIM layer is bonded to the vapor core heat spreader.

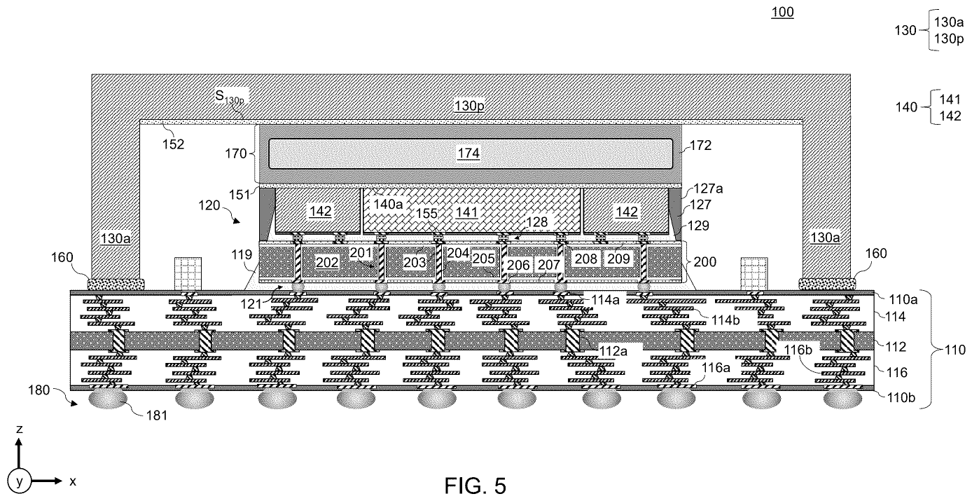

FIG. 5 is a vertical cross-sectional view of the package structure 100 having a first alternative configuration, according to one or more embodiments. As illustrated in FIG. 5, the first alternative configuration may be substantially similar to the original design in FIGS. 1A-1C.

However, in the first alternative configuration, a package lid coating layer 152 may be formed on the bottom surface S130p of the package lid plate portion 130p. The package lid coating layer 152 may be formed of materials substantially similar to the materials of the BSM layer 151. The package lid coating layer 152 may have a thickness substantially similar to the thickness of the BSM layer 151.

As illustrated in FIG. 5, the package lid coating layer 152 may be formed on a substantial entirety of the bottom surface S₁₃₀ₚ of the package lid plate portion 130p. The package lid coating layer 152 may alternatively be formed only on a portion of the bottom surface S₁₃₀ₚ of the package lid plate portion 130p. In particular, the package lid coating layer 152 may be formed only on a portion of the bottom surface S₁₃₀ₚ of the package lid plate portion 130p corresponding to a location of the hybrid TIM structure 170. In at least one embodiment, the package lid coating layer 152 may have a width in the x-direction and length in the y-direction substantially the same as the width and length of the BSM layer 151 (see FIG. 1B).

With the first alternative configuration in FIG. 5, the fourth IMC layer 180d (see FIG. 1C) may be formed between the upper TIM portion 172b and the package lid coating layer 152. The package lid coating layer 152 may include a material that is different from a material of the package lid plate portion 130p. In particular, the package lid coating layer 152 may include a material that provides improved formation of the fourth IMC layer 180d compared to a material of the package lid plate portion 130p. Therefore, the package lid coating layer 152 may help to provide a stronger bond between the package lid plate portion 130p and the hybrid TIM structure 170.

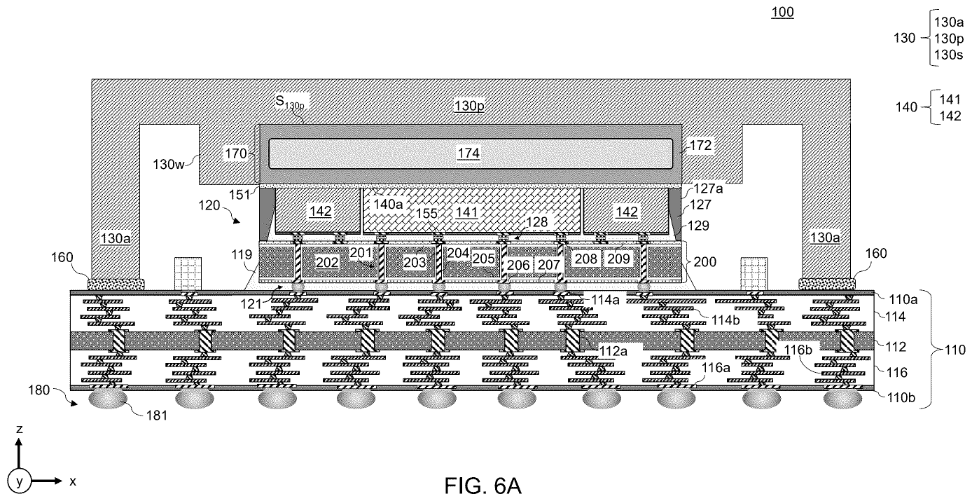

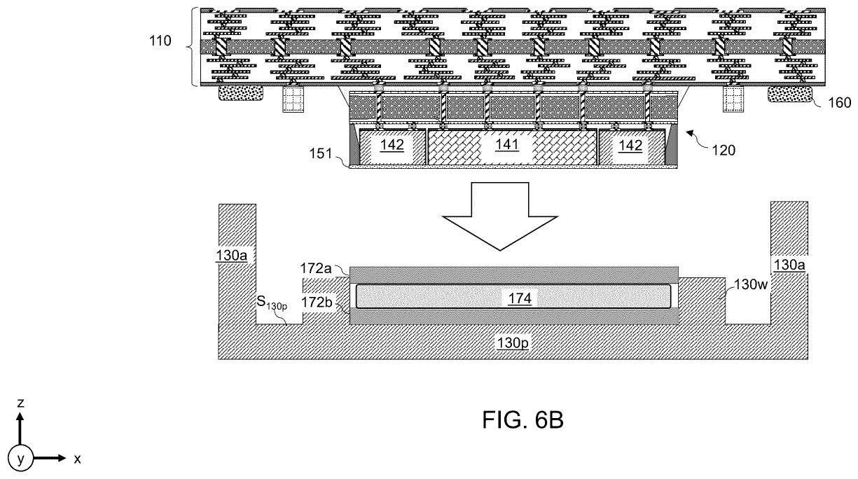

FIGS. 6A-6B are views of the package structure 100 having a second alternative configuration, according to one or more embodiments. In particular, FIG. 6A is a vertical cross-sectional view of the package structure 100 having the second alternative configuration, according to one or more embodiments. FIG. 6B is a vertical cross-sectional view of an intermediate structure in the making of the second alternative configuration of the package structure 100 according to one or more embodiments.

As illustrated in FIG. 6A, the second alternative configuration may be substantially similar to the original configuration in FIGS. 1A-1C. However, in the second alternative configuration, the package lid 130 may additionally include a package lid wall structure 130w. The package lid wall structure 130w may project down from the bottom surface S130p of the package lid plate portion 130p. The package lid wall structure 130w may have a frame-shape. The package lid wall structure 130w may be formed of substantially the same materials as the package lid plate portion 130p. The package lid wall structure 130w may be integrally-formed with the package lid plate portion 130p.

The package lid wall structure 130w may have a thickness substantially the same as the height H2 of the hybrid TIM structure 170 (see FIG. 2C). The package lid wall structure 130w may be formed around an entire periphery of the hybrid TIM structure 170. The package lid wall structure 130w may contact the side of the hybrid TIM structure 170 around the entire periphery of the hybrid TIM structure 170. With this configuration, the package lid wall structure 130w may help to dissipate heat in the hybrid TIM structure 170 in a lateral direction.

As illustrated in FIG. 6B, a method of making the second alternative configuration of the package structure 100 may be slightly different than the method of making the package structure in FIGS. 1A-1C. In particular, instead of placing the three elements of the hybrid TIM structure 170 (e.g., the lower TIM portion 172a, vapor core heat spreader 174 and upper TIM portion 172b) on the semiconductor module 120 as illustrated in FIGS. 3G-3M, in the second alternative configuration, the package lid 130 may be inverted and placed on a table or other support structure. The three elements of the hybrid TIM structure 170 may then be formed on the bottom surface S130p of the package lid plate portion 130p inside the package lid wall structure 130w. In particular, the upper TIM portion 172b may be placed on the bottom surface S₁₃₀ₚ of the package lid plate portion 130p. The vapor core heat spreader 174 may then be placed on the upper TIM portion 172b and the lower TIM portion 172a placed on the vapor core heat spreader 174. The package substrate 110 including the semiconductor module 120, SMDs 190 and adhesive 160 may then be inverted and attached to the package lid 130 by lowering the package substrate 110 onto the package lid 130. The formation of the BGA 180 and heat clamping process may then be performed to complete formation of the package structure 100. During the heat clamping process, the lower TIM portion 172a and upper TIM portion 172b may soften or melt, allowing them to flow along an inner wall of the package lid wall structure 130w to form the lower TIM portion outer wall 172aO and the upper TIM portion outer wall 172bO, respectively (see FIG. 1C).

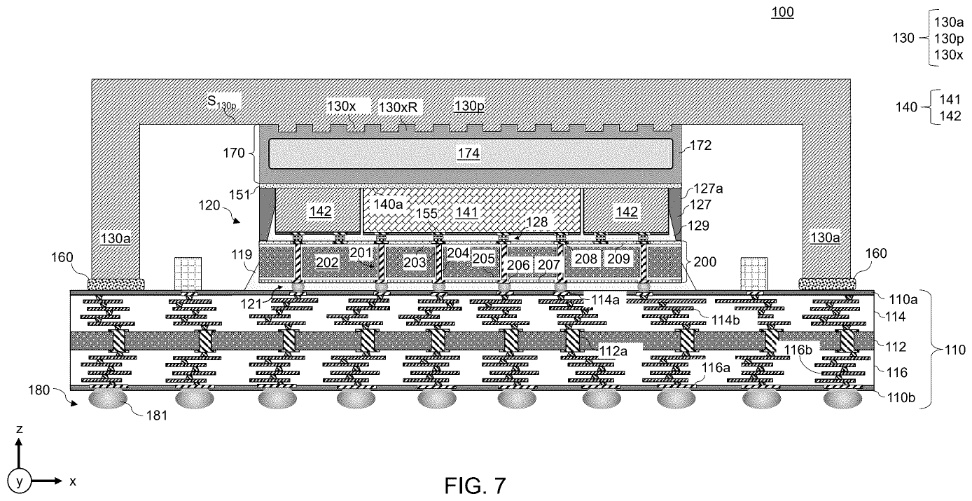

FIG. 7 is a vertical cross-sectional view of a package structure 100 having a third alternative configuration, according to one or more embodiments. As illustrated in FIG. 7, in the fourth alternative configuration, the package lid 130 may include a plurality of projections 130x projecting downwardly from the bottom surface S130p of the package lid plate portion 130p. In at least one embodiment, the projections 130x may be formed in a plurality of rows and columns constituting a two dimensional array. In at least one embodiment, the package lid coating layer 152 (not shown; see FIG. 5) may be formed in the recesses 130xR between the projections 130x.

In making the package structure 100 having the third alternative configuration, when the package lid plate portion 130p is pressed onto to the hybrid TIM structure 170, the TIM layer 172 may be forced into the recesses 130xR. In at least one embodiment, the TIM layer 172 may substantially fill the plurality of recesses 130xR.

With the fourth alternative configuration of the package structure 100, the surface area of the package lid plate portion 130p contacting the hybrid TIM structure 170 may be significantly increased. Therefore, an area of interface between the package lid plate portion 130p and the hybrid TIM structure 170 may be significantly increased, and adhesion between the package lid plate portion 130p and the hybrid TIM structure 170 may be significantly increased.

Referring to FIGS. 1A-7, a package structure 100 may include a package substrate 110, a semiconductor module 120 on the package substrate 110, a package lid 130 on the semiconductor module 120 and attached to the package substrate 110, and a hybrid thermal interface material (TIM) structure 170 between the semiconductor module 120 and the package lid 130, including a TIM layer 172, and a vapor core heat spreader 174 in the TIM layer 172.

In one embodiment, a width W1 of the vapor core heat spreader 174 may be less than a width W2a/W2b of the TIM layer 172 such that the vapor core heat spreader 174 may be entirely surrounded by the TIM layer 172. In one embodiment, the TIM layer 172 may include at least one of indium, indium base alloy, solder, and solder base alloy and may be bonded to the vapor core heat spreader 174 by an intermetallic compound (IMC) layer. In one embodiment, the TIM layer 172 may include a lower TIM portion 172a on a lower surface of the vapor core heat spreader 174, and an upper TIM portion 172b on an upper surface of the vapor core heat spreader 174. In one embodiment, the package structure 100 may further include a backside metal layer 151 on an upper surface of the semiconductor module 120, wherein the lower TIM portion 172a contacts the backside metal layer 151. In one embodiment, the package structure 100 may further include a first intermetallic compound (IMC) layer 180a between the backside metal layer 151 and the lower TIM portion 172a, a second IMC layer 180b between the lower TIM portion 172a and the vapor core heat spreader 174, a third IMC layer 180c between the upper TIM portion 172b and the vapor core heat spreader 174, and a fourth IMC layer 180d between the upper TIM portion 172b and the package lid 130. In one embodiment, the lower TIM portion 172a may include a lower TIM portion outer wall 172aO on a side of the vapor core heat spreader 174, and the upper TIM portion 172b may include an upper TIM portion outer wall 172bO on the side of the vapor core heat spreader 174 and contacting the lower TIM portion outer wall 172aO. In one embodiment, the material of the lower TIM portion 172a may be different than a material of the upper TIM portion 172b. In one embodiment, the package structure 100 may further include an outer wall intermetallic compound (IMC) layer 180e between the lower TIM portion outer wall 172aO and the upper TIM portion outer wall 172bO. A width W2a of the lower TIM portion 172a may be substantially the same as a width W2b of the upper TIM portion 172b. In one embodiment, the thickness Ta1 of the lower TIM portion 172a may be substantially the same as a thickness Ta2 of the upper TIM portion 172b. In one embodiment, the height H1 of the vapor core heat spreader 174 may be less than a width W1 of the vapor core heat spreader 174. In one embodiment, the height H1 of the vapor core heat spreader 174 may be in a range from 0.05 mm to 0.5 mm. In one embodiment, the height H2 of the hybrid TIM structure 170 may be less than or equal to 1 mm.

Referring again to FIGS. 1A-7, a method of forming a package structure 100 may include forming a backside metal layer 151 on an upper surface of a semiconductor module 120, attaching the semiconductor module 120 to a package substrate 110, forming a hybrid TIM structure 170 on the backside metal layer 151, wherein the hybrid TIM structure 170 may include a TIM layer 172 and a vapor core heat spreader 174 in the TIM layer 172, attaching a package lid 130 to the package substrate 110, and heat clamping the package lid 130 to the package substrate 110 such that the TIM layer 172 may be bonded to the vapor core heat spreader 174.

In one embodiment, the forming of the hybrid TIM structure 170 may include forming a lower TIM portion 172a of the TIM layer 172 on the backside metal layer 151, forming the vapor core heat spreader 174 on the lower TIM portion 172a, and forming an upper TIM portion 172b of the TIM layer 172 on an upper surface of the vapor core heat spreader 174. In one embodiment, the heat clamping of the package lid 130 to the package substrate 110 may include forming a first intermetallic compound (IMC) layer 180a between the backside metal layer 151 and the lower TIM portion 172a, forming a second IMC layer 180b between the lower TIM portion 172a and the vapor core heat spreader 174, forming a third IMC layer 180c between the upper TIM portion 172b and the vapor core heat spreader 174, and forming a fourth IMC layer 180d between the upper TIM portion 172b and the package lid 130. In one embodiment, the heat clamping of the package lid 130 to the package substrate 110 further may include forming a lower TIM portion outer wall 172aO of the lower TIM portion 172a on a side of the vapor core heat spreader 174, and forming an upper TIM portion outer wall 172bO of the upper TIM portion 172b on the side of the vapor core heat spreader 174 and contacting the lower TIM portion outer wall 172aO. In one embodiment, the material of lower TIM portion 172a may be different than a material of the upper TIM portion 172b, and the heat clamping of the package lid 130 to the package substrate 110 further may include forming an outer wall intermetallic compound (IMC) layer 180e between the lower TIM portion outer wall 172aO and the upper TIM portion outer wall 172bO.

Referring again to FIGS. 1A-7, a package structure 100 may include a package substrate 110, a semiconductor module 120 on the package substrate 110, including a primary die 141 and a plurality of secondary dies 142 on opposing sides of the primary die 141, a package lid 130 on the semiconductor module 120 and attached to the package substrate 110, and a hybrid thermal interface material (TIM) structure 170 between the semiconductor module 120 and the package lid 130, including a TIM layer 172, and a vapor core heat spreader 174 in the TIM layer 172, wherein at least a portion of the vapor core heat spreader 174 may be located over the plurality of secondary dies 142.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a package substrate;
a semiconductor module on the package substrate;
a package lid on the semiconductor module and attached to the package substrate; and
a hybrid thermal interface material (TIM) structure between the semiconductor module and the package lid, the hybrid TIM structure comprising:
a TIM layer; and
a vapor core heat spreader in the TIM layer.

2. The package structure of claim 1, wherein a width of the vapor core heat spreader is less than a width of the TIM layer such that the vapor core heat spreader is entirely surrounded by the TIM layer.

3. The package structure of claim 1, wherein the TIM layer comprises at least one of indium, indium base alloy, solder, and solder base alloy and is bonded to the vapor core heat spreader by an intermetallic compound (IMC) layer.

4. The package structure of claim 1, wherein the TIM layer comprises:
a lower TIM portion on a lower surface of the vapor core heat spreader; and
an upper TIM portion on an upper surface of the vapor core heat spreader.

5. The package structure of claim 4, further comprising:
a backside metal layer on an upper surface of the semiconductor module, wherein the lower TIM portion contacts the backside metal layer.

6. The package structure of claim 5, further comprising:
a first intermetallic compound (IMC) layer between the backside metal layer and the lower TIM portion;
a second IMC layer between the lower TIM portion and the vapor core heat spreader;
a third IMC layer between the upper TIM portion and the vapor core heat spreader; and
a fourth IMC layer between the upper TIM portion and the package lid.

7. The package structure of claim 4, wherein the lower TIM portion comprises a lower TIM portion outer wall on a side of the vapor core heat spreader, and the upper TIM portion comprises an upper TIM portion outer wall on the side of the vapor core heat spreader and contacting the lower TIM portion outer wall.

8. The package structure of claim 7, wherein a material of the lower TIM portion is different than a material of the upper TIM portion.

9. The package structure of claim 8, further comprising:
an outer wall intermetallic compound (IMC) layer between the lower TIM portion outer wall and the upper TIM portion outer wall.

10. The package structure of claim 4, wherein a width of the lower TIM portion is substantially the same as a width of the upper TIM portion.

11. The package structure of claim 4, wherein a thickness of the lower TIM portion is substantially the same as a thickness of the upper TIM portion.

12. The package structure of claim 1, wherein a height of the vapor core heat spreader is less than a width of the vapor core heat spreader.

13. The package structure of claim 1, wherein a height of the vapor core heat spreader is in a range from 0.05 mm to 0.5 mm.

14. The package structure of claim 1, wherein a height of the hybrid TIM structure is less than or equal to 1 mm.

15. A method of forming a package structure, the method comprising:
forming a backside metal layer on an upper surface of a semiconductor module;
attaching the semiconductor module to a package substrate;
forming a hybrid TIM structure on the backside metal layer, wherein the hybrid TIM structure comprises a TIM layer and a vapor core heat spreader in the TIM layer;
attaching a package lid to the package substrate; and
heat clamping the package lid to the package substrate such that the TIM layer is bonded to the vapor core heat spreader.

16. The method of claim 15, wherein the forming of the hybrid TIM structure comprises:
forming a lower TIM portion of the TIM layer on the backside metal layer;
forming the vapor core heat spreader on the lower TIM portion; and
forming an upper TIM portion of the TIM layer on an upper surface of the vapor core heat spreader.

17. The method of claim 16, wherein the heat clamping of the package lid to the package substrate comprises:
forming a first intermetallic compound (IMC) layer between the backside metal layer and the lower TIM portion;
forming a second IMC layer between the lower TIM portion and the vapor core heat spreader;
forming a third IMC layer between the upper TIM portion and the vapor core heat spreader; and
forming a fourth IMC layer between the upper TIM portion and the package lid.

18. The method of claim 17, wherein the heat clamping of the package lid to the package substrate further comprises:
forming a lower TIM portion outer wall of the lower TIM portion on a side of the vapor core heat spreader; and
forming an upper TIM portion outer wall of the upper TIM portion on the side of the vapor core heat spreader and contacting the lower TIM portion outer wall.

19. The method of claim 18, wherein a material of lower TIM portion is different than a material of the upper TIM portion, and the heat clamping of the package lid to the package substrate further comprises:
forming an outer wall intermetallic compound (IMC) layer between the lower TIM portion outer wall and the upper TIM portion outer wall.

20. A package structure, comprising:
a package substrate;
a semiconductor module on the package substrate, comprising a primary die and a plurality of secondary dies on opposing sides of the primary die;
a package lid on the semiconductor module and attached to the package substrate; and
a hybrid thermal interface material (TIM) structure between the semiconductor module and the package lid, the hybrid TIM structure comprising:
a TIM layer; and
a vapor core heat spreader in the TIM layer, wherein at least a portion of the vapor core heat spreader is located over the plurality of secondary dies.
